(19) United States
(12) Patent Application Publication
(10) Pub. No.: US 2026/0173518 A1
(43) Pub. Date: Jun. 18, 2026

(54) INTEGRATED CIRCUIT DEVICE AND MANUFACTURING METHOD THEREOF

(71) Applicant: Samsung Electronics Co., Ltd., Suwon-si (KR)

(72) Inventors: Woohyeon CHOI, Suwon-si (KR); Kyunam PARK, Suwon-si (KR)

(73) Assignee: Samsung Electronics Co., Ltd., Suwon-si (KR)

(21) Appl. No.: 19/238,884

(22) Filed: Jun. 16, 2025

(30) Foreign Application Priority Data
Dec. 12, 2024 (KR) 10-2024-0185200

(51) Int. Cl. H10D 84/85; H10D 84/01

(52) U.S. Cl. CPC H10D 84/856; H10D 84/0167; H10D 84/0188; H10D 84/852

(57) ABSTRACT

Provided is an integrated circuit device including a substrate, a first insulating pillar extending in a first direction intersecting a surface of the substrate, a first channel structure including a first sheet and a second sheet, the first sheet and the second sheet spaced apart in a second direction intersecting the first direction with the first insulating pillar interposed between the first sheet and the second sheet in the second direction, a second insulating pillar spaced apart from the first insulating pillar in the second direction on the substrate, and a second channel structure including a third sheet and a fourth sheet, the third sheet and the fourth sheet spaced apart in the second direction with the second insulating pillar interposed between the third sheet and the fourth sheet in the second direction.

### CROSS-REFERENCE TO RELATED APPLICATIONS

This application claims the benefit of and priority to Korean Patent Application No. 10-2024-0185200, filed on Dec. 12, 2024, in the Korean Intellectual Property Office, the disclosure of which is incorporated herein by reference in its entirety.

### BACKGROUND

Example embodiments relate to integrated circuit devices and methods of manufacturing the same.

With the rapid spread of information media, the functions of semiconductor devices are also developing rapidly. In the case of recent semiconductor products, in order to secure competitiveness, high integration of products is required for low cost and high quality. To achieve high integration, integrated circuit devices are being scaled down.

Meanwhile, as down-scaling of integrated circuit devices progresses rapidly, in integrated circuit devices, it is necessary to secure not only fast operating speed but also operational accuracy. Accordingly, various studies are being conducted to provide integrated circuit devices with a structure that can provide optimal performance and improve reliability.

### SUMMARY

An aspect of the example embodiments provides integrated circuit devices by which integration and/or electrical reliability may be improved.

An aspect of the example embodiments provides methods of manufacturing the integrated circuit device by which integration and/or electrical reliability may be improved.

The technical tasks to be achieved by the present example embodiments are not limited to the technical tasks described above, and other technical tasks may be inferred from the following example embodiments by those skilled in the art.

According to some example embodiments, there is provided an integrated circuit device including a substrate, a first insulating pillar extending in a first direction intersecting a surface of the substrate, a first channel structure including a first sheet and a second sheet, the first sheet and the second sheet spaced apart in a second direction intersecting the first direction with the first insulating pillar interposed between the first sheet and the second sheet in the second direction, a second insulating pillar spaced apart from the first insulating pillar in the second direction on the substrate; and a second channel structure including a third sheet and a fourth sheet, the third sheet and the fourth sheet spaced apart in the second direction with the second insulating pillar interposed between the third sheet and the fourth sheet in the second direction, wherein a sum of a width of the first channel structure and a width of the first insulating pillar in the second direction is equal to a sum of a width of the second channel structure and a width of the second insulating pillar in the second direction, and the width of the first channel structure in the second direction is greater than the width of the second channel structure in the second direction.

According to some example embodiments, there is provided an integrated circuit device including a substrate, a first insulating pillar extending in a first direction intersecting a surface of the substrate, a plurality of first nano sheets extending from the first insulating pillar in a second direction parallel to the surface of the substrate, the plurality of first nano sheets arranged in the first direction, a plurality of second nano sheets extending toward the first insulating pillar in the second direction, the plurality of second nano sheets arranged in the first direction, a second insulating pillar spaced apart from the first insulating pillar in the second direction on the substrate, a plurality of third nano sheets extending from the second insulating pillar along the second direction, the plurality of third nano sheets arranged in the first direction, and a plurality of fourth nano sheets extending from the second insulating pillar along the second direction, the plurality of fourth nano sheets arranged in the first direction, wherein a width of the plurality of first nano sheets in the second direction is greater than a width of the plurality of second nano sheets in the second direction.

According to some example embodiments, there is provided an integrated circuit device including a substrate having a plurality of active areas, a plurality of field insulating films that are spaced apart from each other on the substrate in a first direction parallel to a surface of the substrate, the plurality of field insulating films defining the plurality of active areas, a first insulating pillar extending in a second direction intersecting the first direction, the first insulating pillar between a pair of adjacent field insulating films among the plurality of field insulating films, a second insulating pillar spaced apart from the first insulating pillar in the first direction on the substrate, a plurality of first nano sheets extending from a first side wall of the first insulating pillar and arranged in parallel in a third direction intersecting the surface of the substrate, a plurality of second nano sheets extending from a second side wall opposite to the first side wall of the first insulating pillar and arranged in parallel in the third direction, a plurality of third nano sheets extending from a third side wall of the second insulating pillar and arranged in parallel in the third direction, a plurality of fourth nano sheets extending from a fourth side wall opposite to the third side wall of the second insulating pillar and arranged in parallel in the third direction, a plurality of p-type source/drain positioned in the second direction from the plurality of first nano sheets and the plurality of second nano sheets, and a plurality of n-type source/drain areas positioned in the second direction from the plurality of third nano sheets and the plurality of fourth nano sheets, wherein a sum of a width of the plurality of first nano sheets, a width of the plurality of second nano sheets and a width of the first insulating pillar in the first direction is equal to a sum of a width of the plurality of third nano sheets, a width of the plurality of fourth nano sheets and a width of the second insulating pillar in the first direction, the width of the plurality of first nano sheets in the first direction is equal to the width of the plurality second nano sheet in the first direction, and the width of the plurality of first nano sheets is greater than the width of the plurality of third nano sheets in the first direction and the width of the plurality of fourth nano sheets in the first direction.

According to some example embodiments, there is provided a method of manufacturing an integrated circuit device including forming a laminated structure on a substrate, in which a plurality of sacrificial layers and a plurality of semiconductor layers are alternately stacked in a first direction, forming a plurality of trenches penetrating the laminated structure, wherein the trenches have different widths from each other, depositing an insulating material in some of the plurality of trenches to form a first field insulating film, a second field insulating film, and a third field insulating film, which are spaced apart from each other in a second direction intersecting the first direction, and forming a plurality of recesses penetrating the plurality of semiconductor layers in the first direction, wherein the recesses have different widths from each other, to form a first nano sheet structure and a second nano sheet structure, which are spaced apart from each other in the second direction, wherein a distance between a center of a first field insulating film and a center of a second field insulating film in the second direction is equal to a distance between a center of the second field insulating film and a center of a third field insulating film in the second direction, and wherein a width of a first nano sheet structure in the second direction is greater than a width of a second nano sheet structure in the second direction.

According to some example embodiments, there is provided a method of manufacturing an integrated circuit device including forming a laminated structure on a substrate, the laminated structure including a stack of semiconductor layers and sacrificial layers the semiconductor layers and the sacrificial layers alternating in a first direction; patterning the laminate structure to form a plurality of first trenches and a plurality of second trenches, the plurality of first trenches and the plurality of second trenches alternating in a second direction; forming a first insulating pillar in a first trench of the plurality of first trenches; depositing an insulating material in the plurality of second trenches to form a plurality of field insulating films including a first field insulating film, a second field insulating film, and a third field insulating film such that the first insulating pillar is between the first field insulating film and the second field insulating film; and forming a plurality of recesses penetrating the semiconductor layers in the first direction to form a first nano sheet structure between the first insulating pillar and the first field insulating film and a second nano sheet structure between the first insulating pillar and the second field insulating film, the first nano sheet structure having a first width in the second direction and the second nano sheet structure having a second width in the second direction, the first width being different from the second width.

### BRIEF DESCRIPTION OF THE FIGURES

These and/or other aspects, features, and advantages of the inventive concepts will become apparent and more readily appreciated from the following description of example embodiments, taken in conjunction with the accompanying drawings of which:

FIG. 1 is a planar layout diagram illustrating an integrated circuit device according to some example embodiments;

FIG. 2 is a drawing illustrating a cross-section taken along line A1-A1′ of FIG. 1;

FIG. 3 is a drawing illustrating an enlarged view of the portion indicated as “CX” in FIG. 2;

FIG. 4 is a drawing illustrating a cross-section taken along line A2-A2′ of FIG. 1;

FIG. 5 is a drawing illustrating a cross-section taken along line B-B′ of FIG. 1;

FIG. 6 is a planar layout diagram illustrating an integrated circuit device according to some example embodiments of the present disclosure;

FIG. 7A a drawing illustrating a cross-section taken along line A1_a-A1_a′ of FIG. 6;

FIG. 7B is a drawing illustrating a cross-section taken along line A2_a-A2_a′ of FIG. 6;

FIG. 8 is a planar layout diagram illustrating an integrated circuit device according to some example embodiments of the present disclosure;

FIG. 9A is a drawing illustrating a cross-section taken along line A1_b-A1_b′ of FIG. 8;

FIG. 9B is a drawing illustrating a cross-section taken along line A2_b-A2_b′ of FIG. 8;

FIG. 10A to FIG. 25C are cross-sectional views illustrating a process sequence for explaining methods of manufacturing integrated circuit devices according to some example embodiments, FIG. 10A, FIG. 11, FIG. 12A, FIG. 13, FIG. 14A, FIG. 15, FIG. 16, FIG. 17, FIG. 18A, FIG. 19A, FIG. 22, FIG. 23A, FIG. 24A and FIG. 25A are cross-sectional views illustrating cross-sectional structures according to the process sequence of the part corresponding to the cross-section along line A1-A1′ of FIG. 1, FIG. 24B and FIG. 25C are cross-sectional views illustrating cross-sectional structures according to the process sequence of a portion corresponding to the B-B′ cross-section of FIG. 1, and FIG. 20, FIG. 21A, and FIG. 25B are cross-sectional views illustrating cross-sectional structures according to the process sequence of a portion corresponding to the cross-section taken along line A2-A2′ of FIG. 1;

FIG. 26 to FIG. 30 are cross-sectional views illustrating a process sequence for explaining methods of manufacturing an integrated circuit device according to some example embodiments of the present disclosure, FIG. 26 to FIG. 28 are cross-sectional views showing cross-sectional structures according to the process sequence of a portion corresponding to the cross-section along line A1_a-A1_a′ of FIG. 6, and FIG. 29 and FIG. 30 are cross-sectional views illustrating cross-sectional structures according to the process sequence of a part corresponding to the cross-section along line A2_a-A2_a′ of FIG. 6; and

FIG. 31 to FIG. 35 are cross-sectional views illustrating a process sequence for explaining methods of manufacturing integrated circuit devices according to some example embodiments of the present disclosure, FIG. 31 to FIG. 33 are cross-sectional views illustrating cross-sectional structures according to the process sequence of a part corresponding to the cross-section along line A1_b-A1_b′ of FIG. 8, and FIG. 34 and FIG. 35 are cross-sectional views illustrating cross-sectional structures according to the process sequence of a part corresponding to the cross-section along line A2_b-A2_b′ of FIG. 8.

### DETAILED DESCRIPTION

Terms or words used in the specification and claims should not be construed as limited to their common or dictionary meanings. Further, the terms or words should be interpreted with meaning and concept consistent with the inventive concepts of the present disclosure based on the principle that the inventors may appropriately define the concepts and/or terms in order to explain the inventive concepts in the best way. The example embodiments described in this specification and the configurations shown in the drawings are only example embodiments of the present disclosure, and do not represent the entirety of the inventive concepts of the present disclosure. Accordingly, at the time of filing the present disclosure, there may be various equivalents and modifications that can replace them.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

In the present disclosure, singular expressions include plural expressions unless the context clearly indicates otherwise. Further, terms “first,” “second” and so on may be used to describe various components. However, the components are not limited by the terms, and the terms may be used for the purpose of distinguishing one component from another. Within the scope of the technical idea of the present disclosure, the first component may be named as the second component. Similarly, the second component may also be named the first component. Further, the shape and size of components may be exaggerated to emphasize clear explanation.

Further, in the following description, expressions such as an upper side, top, a lower side, bottom, a side, front and a back side are expressed based on the direction shown in the drawing. If the direction of the object changes, it may be expressed differently. The shapes and sizes of elements in the drawings may be exaggerated for clearer explanation.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

Hereinafter, some example embodiments according to the inventive concepts of the present disclosure will be described with reference to the attached drawings.

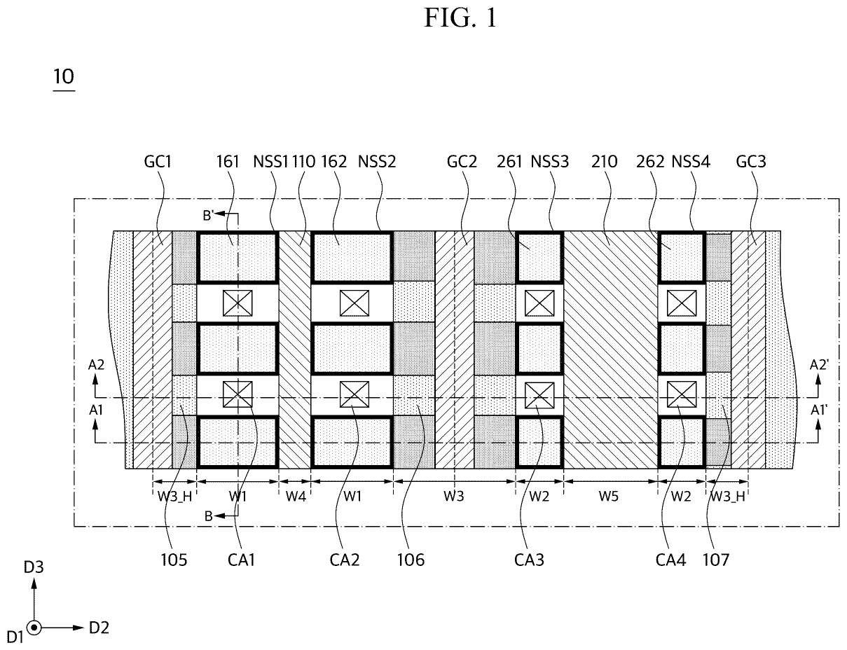

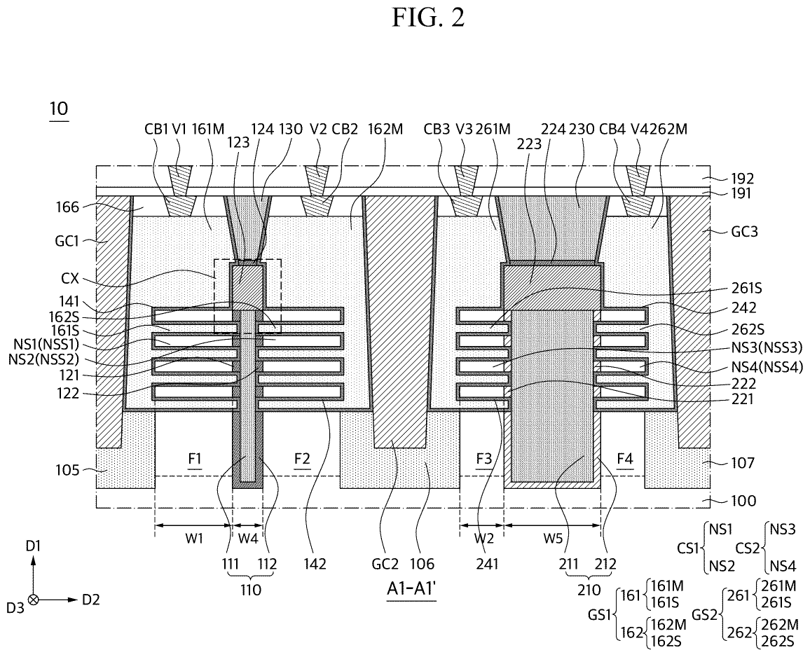

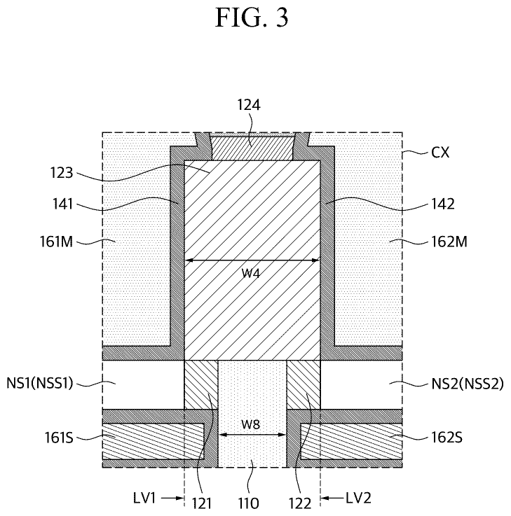

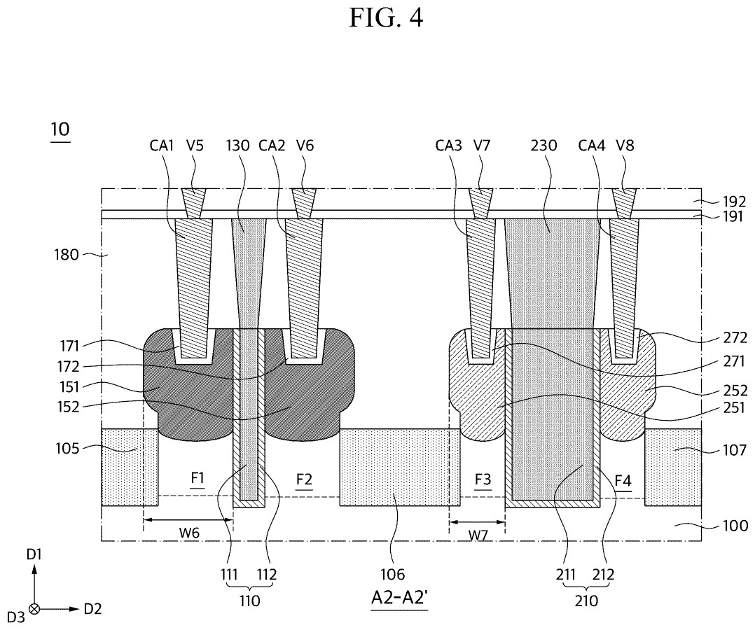

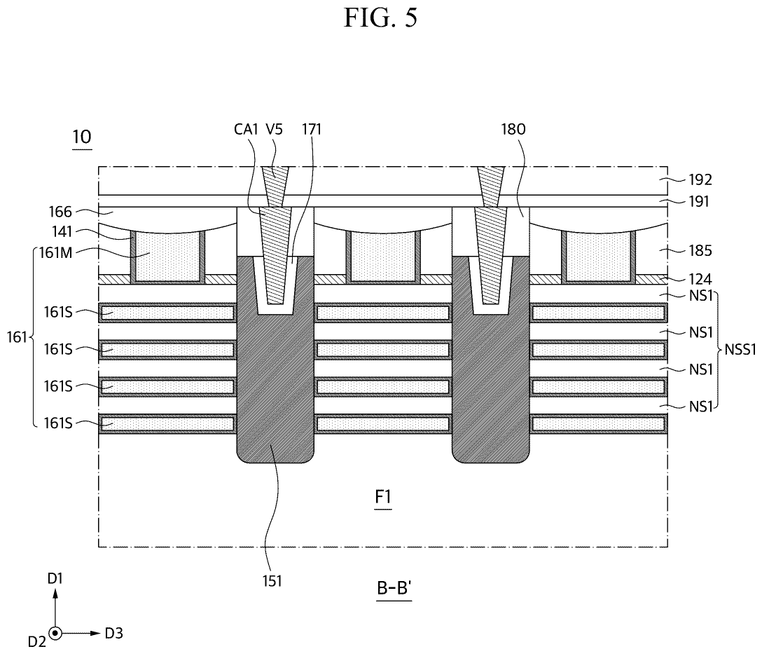

FIG. 1 is a planar layout diagram illustrating an integrated circuit device 10 according to some example embodiments of the inventive concepts of the present disclosure. FIG. 2 is a cross-sectional view taken along line A1-A1′ of FIG. 1. FIG. 3 is an enlarged cross-sectional view of the portion indicated as “CX” in FIG. 2. FIG. 4 is a cross-sectional view taken along line A2-A2′ of FIG. 1. FIG. 5 is a cross-sectional view taken along line B-B′ of FIG. 1. The integrated circuit device 10 according to some example embodiments of the present disclosure is described with reference to FIG. 1 to FIG. 5 below.

Referring to FIG. 1 to FIG. 5, the integrated circuit device 10 according to some example embodiments of the present disclosure may include a substrate 100, a first field insulating film 105, a second insulating film 106, a third field insulating film 107, a first insulating pillar 110 and a second insulating pillar 210, a first barrier 121, a second barrier 122, and a third barrier, 221, a fourth barrier 222, a first insulating cap 123 and a second insulating cap 223, the first upper insulting pillar 130 and a second upper insulting pillar 230, the first gate dielectric film 141, a second gate dielectric film 142, a third gate dielectric film 241, a fourth gate dielectric film 242, a first source/drain area 151, a second source/drain area 152, a third source/drain area 251, a fourth source/drain area 252, a first gate line 161, a second gate line 162, a third gate line 261, a fourth gate line 262, a first silicide layer 171, a second silicide layer 172, a third silicide layer 271, a fourth silicide layer 272, a capping pattern 166, a first interlayer insulating film 180 and a second interlayer insulating film 192, an etching stopping film 191, a first gate contact CB1, a second gate contact CB2, a third gate contact CB3, a fourth gate contact CB4, a first source/drain contact CA1, a second source/drain contact CA2, third source/drain contact CA3, a fourth source/drain contact CA4, a first gate cut GC1, a second gate cut GC2, a third gate cut GC3, a first nano sheet stack NSS1, a second nano sheet stack NSS2, a third nano sheet stack NSS3, a fourth nano sheet stack NSS4, and a first via V1 to an eighth via V8.

According to some example embodiments, the substrate 100 may be a silicon substrate or a silicon-on-insulator (SOI). Alternatively, the substrate 100 may include silicon germanium, silicon germanium on insulator (SGOI), indium antimonide, lead telluride, indium arsenide, indium phosphide, gallium arsenide or gallium antimonide, but the technical idea of the present disclosure is not limited thereto.

According to some example embodiments, each of a first active area F1 to a fourth active area F4 may protrude in the first direction D1 from the substrate 100. In the present disclosure, the first direction D1 may be defined as a direction intersecting each of the second direction D2 and the third direction D3, which is different from the second direction D2. Each of the first active area F1 to the fourth active area F4 may be part of the substrate 100, and may include an epitaxial layer grown from the substrate 100. Each of the first active area F1 to the fourth active area F4 may be extended in the third direction D3. In the present disclosure, the third direction D3 may be defined as the direction in which the first active area F1 to the fourth active area F4 extends. The substrate 100 may be extended in the second direction D2 and/or the third direction D3.

According to some example embodiments, the first active area F1 to the fourth active area F4 may be spaced apart from each other in the second direction D2, one by one. Here, the first active area F1, a second active area F2, a third active area F3, and the fourth active area F4 may be arranged in sequence in the second direction D2.

According to some example embodiments, the first field insulating film 105 to the third field insulating film 107 may be disposed on the substrate 100. The first field insulating film 105 to the third field insulating film 107 may cover side walls of the first active area F1 to the fourth active area F4. More specifically, one side of the first active area F1 in the second direction D2 may be covered by the first field insulating film 105, and the other side that is opposite to the one side may be covered by the first insulating pillar 110. Further, one side of the second active area F2 may be covered by a second field insulating film 106, and the other side that is opposite to the one side may be covered by the first insulating pillar 110. One side of the third active area F3 may be covered by the second field insulating film 106, and the other side that is opposite to the one side may be covered by the second insulating pillar 210. One side of the fourth active area F4 may be covered by the third field insulating film 107, and the other side that is opposite to the one side may be covered by the second insulating pillar 210.

For example, FIG. 2 illustrates that the upper surface of each of the first active area F1 to the fourth active area F4 is formed on the same plane as the upper surface of the first field insulating film 105 to the third field insulating film 107. However, the technical idea of the present disclosure is not limited thereto. In some example embodiments, the upper surface of each of the first active area F1 to the fourth active area F4 may protrude relative to or further than the upper surface of the first field insulating film 105 to the third field insulating film 107 in the first direction D1.

According to some example embodiments, the first insulating pillar 110 may extend in the third direction D3 in the space between the adjacent first field insulating film 105 and second field insulating film 106. More specifically, the bottom part of the first insulating pillar 110 may be interposed between the first active area F1 and the second active area F2, and may be extended in the third direction D3 and at the same time in the first direction D1. The first insulating pillar 110 may act as a separating film between the first active area F1 and the second active area F2. In addition thereto, the top part of the first insulating pillar 110 may be interposed between the first gate line 161 and a second gate line 162, and be interposed between a first nano sheet NS1 and a second nano sheet NS2.

According to some example embodiments, the second insulating pillar 210 may extend in the third direction D3 in the space between the adjacent second field insulating film 106 and third field insulating film 107. More specifically, the bottom part of the second insulating pillar 210 may be interposed between the third active area F3 and the fourth active area F, and be extended in the third direction D3 and in the first direction D1 at the same time. The second insulating pillar 210 may act as a separating film between the third active area F3 and the fourth active area F4. In addition thereto, the top part of the second insulating pillar 210 may be interposed between a third gate line 261 and the fourth gate line 262, and be interposed between a third nano sheet NS3 and a fourth nano sheet NS4.

According to some example embodiments, the first insulating pillar 110 may be located at the center of the first gate cut GC1 and a second gate cut GC2, which are spaced apart in the second direction D2 with the first insulating pillar 110 in between. Similarly, the second insulating pillar 210 may be located at the center of the second gate cut GC2 and the third gate cut GC3, which are spaced apart in the second direction D2 with the second insulating pillar 210 therebetween.

According to some example embodiments, the first insulating pillar 110 may include a first filling film 111 extending in the first direction D1 and a first insulating liner 112 covering a side wall and a lower surface of the bottom part of the first filling film 111. The upper surface of the first insulating liner 112 may be coplanar with the upper surface of the first active area F1 or the second active area F2. The first insulating pillar 110 may be extended in the first direction D1 while overlapping laterally (D2 direction and/or D3 direction) across the first gate line 161 and the second gate line 162 and the first active area and the second active area F2. Here, the part that overlaps with the first active area and the second active area F2 in the lateral direction (D2 direction and/or D3 direction) in the first insulating pillar 110 may be covered by the first insulating liner 112.

Similarly, the second insulating pillar 210 may include a second filling film 211 extending in the first direction D1 and a second insulating liner 212 covering a side wall and a lower surface of the bottom part of the second filling film 211. The second insulating liner 212 may be positioned to be coplanar with the upper surface of the third active area F3 or the fourth active area F4. The second insulating pillar 210 may be extended to the first direction D1, while overlapping laterally (D2 direction and/or D3 direction) across the third gate line 261 and the fourth gate line 262 and the third active area F3 and the fourth active area F4. Here, the part that overlaps with the third active area F3 and the fourth active area F4 in the lateral direction (D2 direction and/or D3 direction) in the second insulating pillar 210 may be covered with the second insulating liner 212.

According to some example embodiments, the first filling film 111 and the second filling film 211, and the first insulating liner 112 and the second insulating liner 212 may contain different low-k materials. For example, the first filling film 111 and the second filling film 211 include materials having different etch selectivities with respect to the first insulating liner 112 and the second insulating liner 212. In some example embodiments, the first filling film 111 and the second filling film 211, and the first insulating liner 112 and the second insulating liner 212 may include at least one of SiOC, SiOCN, SiN, SiCN, and/or a combination thereof. However, the materials contained in the first filling film 111 and the second filling film 211, and the first insulating liner 112 and the second insulating liner 212 are not limited to the above.

According to some example embodiments, the plurality of nano sheet stacks (the first nano sheet stack NSS1 to the fourth nano sheet stack NSS4) may be arranged on each surface of the first active area F1 to the fourth active area F4. The first nano sheet stack NSS1 may be placed on the first active area F1, and a second nano sheet stack NSS2 may be placed on the second active area F2. Further, a third nano sheet stack NSS3 may be placed on the third active area F3, and the fourth nano sheet stack NSS4 may be placed on the fourth active area F4. The first nano sheet stack NSS1 to the fourth nano sheet stack NSS4 may be sequentially spaced in the second direction D2.

According to some example embodiments, the first nano sheet stack NSS1 may include a plurality of first nano sheets NS1 spaced apart from each other in the first direction D1, and the second nano sheet stack NSS2 may include a plurality of second nano sheets NS2 spaced apart from each other in the first direction D1. The third nano sheet stack NSS3 may include a plurality of third nano sheets NS3 spaced apart from each other in the first direction D1, and the fourth nano sheet stack NSS4 may include a plurality of fourth nano sheets NS4 spaced apart from each other in the first direction D1. Even though FIG. 2 illustrates that the first nano sheet stack NSS1 to the fourth nano sheet stack NSS4 contain four nano sheets spaced apart from each other in the first direction D1, the technical idea of the present disclosure is not limited thereto. In some other example embodiments, each of the first nano sheet stack NSS1 to the fourth nano sheet stack NSS4 may include two, three, or five or more nano sheets spaced apart from each other in the first direction D1.

According to some example embodiments, the first nano sheet NS1 may extend from the first insulating pillar 110 in the direction (−D2 direction) opposite to the second direction. More specifically, the first nano sheet NS1, the first barrier 121, and the first filling film 111 of the first insulating pillar 110 may form an integral body with each other. The second nano sheet NS2 may extend from the first insulating pillar 110 in the second direction D2. The second nano sheet NS2, a second barrier 122, and the first filling film 111 of the first insulating pillar 110 may form an integral body with each other. Similarly, the third nano sheet NS3 may extend from the second insulating pillar 210 in the direction (−D2 direction) opposite to the second direction. More specifically, the third nano sheet NS3, a third barrier 221, and the second filling film 211 of the second insulating pillar 210 may form an integral body with each other. The fourth nano sheet NS4 may extend from the second insulating pillar 210 in the second direction D2. The fourth nano sheet NS4, the fourth barrier 222, and the second filling film 211 of the second insulating pillar 210 may form an integral body with each other.

According to some example embodiments, the first barrier 121 may be interposed between the first nano sheet NS1 and the first filling film 111, and the second barrier 122 may be interposed between the second nano sheet NS2 and the first filling film 111. The third barrier 221 may be interposed between the third nano sheet NS3 and the second filling film 211, and the fourth barrier 222 may be interposed between the fourth nano sheet NS4 and the second filling film 211. Specifically, among the side walls of the plurality of nano sheets (the first nano sheet NS1 to the fourth nano sheet NS4), a side wall facing the first insulating pillar 110 or the second insulating pillar 210 may be covered by the plurality of barriers (the first barrier 121, the second barrier 122, the third barrier 221, and the fourth barrier 222).

According to some example embodiments, the first insulating cap 123 may be provided on the upper surface of the first insulating pillar 110. The first insulating cap 123 may be arranged to be in contact with a portion of the upper surface of the first insulating pillar 110. As illustrated in FIG. 3, one side wall of the first insulating cap 123 may be located at the same first horizontal level LV1 as the side wall of the first barrier 121 located at the uppermost end. Further, the other side wall, opposite to the one side wall of the first insulating cap 123, may be located at a second horizontal level LV2, equal to the side wall of the second barrier 122 located at the uppermost end. The first insulating cap 123 may be provided on the upper surface of a portion of the first insulating pillar 110 interposed between the first nano sheet stack NSS1 and the second nano sheet stack NSS2. The first insulating cap 123 may not be provided on the upper surface of a portion of the first insulating pillar 110 interposed between the first source/drain area 151 and a second source/drain area 152.

According to some example embodiments, the side wall of the first barrier 121 may be located at the same horizontal level as the side wall of the first insulating liner 112. Therefore, since the side wall of the first insulating cap 123 is located at the same first horizontal level LV1 as the side wall of the first barrier 121, the first insulating cap 123 may be located at the same horizontal level as the side wall of the first insulating pillar 110 (e.g., the insulating liner 112). In other words, the width of the first insulating cap 123 may be a fourth width W4, which is the same as the width of the first insulating pillar 110. The first filling film 111 may have an eight width W8 that is smaller than the fourth width W4 of the first insulating cap 123 in the second direction D2.

Similarly, the second insulating cap 223 may be located at the same horizontal level as the side wall of the second insulating pillar 210. Therefore, the width of the second insulating cap 223 may be the same as the width of the second insulating pillar 210, and the second filling film 211 may have a width in the second direction D2 that is smaller than a fifth width W5 of the second insulating cap 223.

According to some example embodiments, the second insulating cap 223 may be provided on the upper surface of the second insulating pillar 210. The second insulating cap 223 may be arranged to be in contact with a portion of the upper surface of the second insulating pillar 210. One side wall of the second insulating cap 223 may be located at the same horizontal level as a side wall of the third barrier 221 located at the uppermost end. Further, the other side wall of the second insulating cap 223, opposite to the one side wall, may be located at the same horizontal level as the side wall of the fourth barrier 222 located at the uppermost end. The second insulating cap 223 may be provided on the upper surface of a portion of the second insulating pillar 210 interposed between the third nano sheet stack NSS3 and the fourth nano sheet stack NSS4. The second insulating cap 223 may not be provided on the upper surface of a portion of the second insulating pillar 210 interposed between a third source/drain area 251 and the fourth source/drain area 252.

As will be described later, according to some example embodiments, in the process of etching the first active area F1 to the fourth active area F4 to form the first source/drain area 151 to the fourth source/drain area 252, the first insulating cap 123 and the second insulating cap 223 may protect the first insulating pillar 110 and the second insulating pillar 210 by utilizing the etching selectivity.

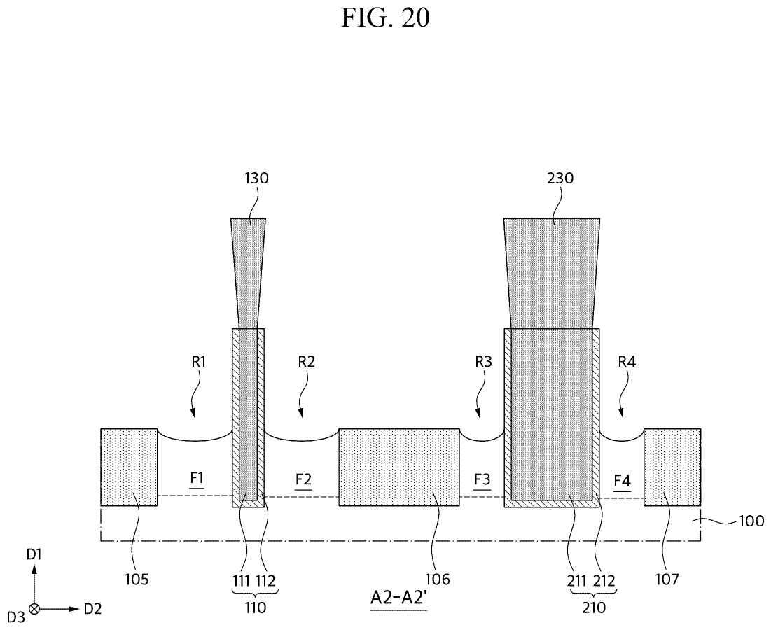

According to some example embodiments, a first upper insulting pillar 130 may be located on the first insulating pillar 110, and the second upper insulting pillar 230 may be located on the second insulating pillar 210. The upper surface of the first insulating pillar 110 interposed between the first nano sheet NS1 and the second nano sheet NS2 may be in contact with the first insulating cap 123. On the other hand, the upper surface of the first insulating pillar 110 interposed between the first source/drain area 151 and the second source/drain area 152 may come into contact with the first upper insulting pillar 130. As will be described later, in order to prevent or reduce the shadowing effect in the process of epitaxial growth for the first source/drain area 151 and the second source/drain area 152, the first insulating cap 123 may not be provided around the recess (see a first recess R1 and a second recess R2 of FIG. 20) that grows the first source/drain area 151 and the second source/drain area 152. As a result, the upper surface of the first insulating pillar 110 interposed between the first source/drain area 151 and the second source/drain area 152 comes into contact with the first super insulting pillar 130, not the first insulating cap 123.

Similarly, in order to prevent or reduce the shadowing effect during the epitaxial growth of the third source/drain area 251 and the fourth source/drain area 252, the second insulating cap 223 may not be provided around the recess (see a third recess R3 and a fourth recess R4 of FIG. 20) that grows the third source/drain area 251 and the fourth source/drain area 252. As a result, the upper surface of the second insulating pillar 210 interposed between the third source/drain area 251 and the fourth source/drain area 252 comes into contact with the second super insulting pillar 230, not the second insulating cap 223.

According to some example embodiments, each of the first gate line to the fourth gate line (the first gate line 161, the second gate line 162, the third gate line 261, and the fourth gate line 262) may extend in the third direction D3 from the active areas (the first active area F1 to the fourth active area F4). The first gate line 161 may surround the first nano sheet stack NSS1 on one side of the first super insulting pillar 130 in the second direction D2. The second gate line 162 may surround the second nano sheet stack NSS2 on the opposite side of the first super insulting pillar 130 in the second direction D2. The third gate line 261 may surround the third nano sheet stack NSS3 on one side of the second super insulting pillar 230 in the second direction D2, and the fourth gate line 262 may surround the fourth nano sheet stack NSS4 on the other side that is opposite to the side of the second super insulting pillar 230 in the second direction D2. According to some example embodiments, the first gate line 161 and the second gate line 162, which are arranged on one side in the second direction D2 based on the second gate cut GC2, may form a first gate structure GS1. Further, the third gate line 261 and the fourth gate line 262, which are arranged on the other side opposite to the one side in the second direction D2 based on the second gate cut GC2, may form a second gate structure GS2.

Specifically, each of the plurality of gate lines (the first gate line 161, the second gate line 162, the third gate line 261, and the fourth gate line 262) may include main gate parts (a first main gate part 161M, a second main gate part 162M, a third main gate part 261M, and a fourth main gate part 262M) covering the upper surfaces of the nano sheet stacks (the first nano sheet stack NSS1 to the fourth nano sheet stack NSS4), and a plurality of sub gate parts (a first sub gate part 161S, a second sub gate part 162S, a third sub gate part 261S, and a fourth sub gate part 262S) connected to the main gate parts (the first main gate part 161M, the second main gate part 162M, the third main gate part 261M, and the fourth main gate part 262M) and formed in the space between the plurality of nano sheets (the first nano sheet NS1 to the fourth nano sheet NS4) and the active areas (the first active area F1 to the fourth active area F4). Each of the plurality of sub gate parts (the first sub gate part 161S, the second sub gate part 162S, the third sub gate part 261S, and the fourth sub gate part 262S) may have a length in the third direction D3 equal to the length of the main gate parts (the first main gate part 161M, the second main gate part 162M, the third main gate part 261M, and the fourth main gate part 262M) in the third direction D3. However, in some example embodiments, the length of the main gate parts (the first main gate part 161M, the second main gate part 162M, the third main gate part 261M, and the fourth main gate part 262M) in the third direction D3 may have a value greater than or less than the length of each of the plurality of sub gate parts (the first sub gate part 161S, the second sub gate part 162S, the third sub gate part 261S, and the fourth sub gate part 262S) in the third direction D3.

According to some example embodiments, each of the first gate line to the fourth gate line (the first gate line 161, the second gate line 162, the third gate line 261, and the fourth gate line 262) may include, for example, at least one of titanium nitride (TiN), tantalum carbide (TaC), tantalum nitride (TaN), and titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof. Each of the first gate line to the fourth gate line (the first gate line 161, the second gate line 162, the third gate line 261, and the fourth gate line 262) may include a conductive metal oxide, a conductive metal oxynitride and so on, and may also include an oxidized form of the above-described substance.

According to some example embodiments, the first source/drain area 151 may be placed on at least one side of the first gate line 161 on the first active area F1. For example, a plurality of first source/drain areas 151 spaced apart from each other may be provided in the third direction D3. A pair of first source/drain areas 151 may be placed on both sides of the first gate line 161 in the third direction D3 on the first active area F1. Further, the first source/drain areas 151 may be arranged between a plurality of first nano sheets stack NSS1 arranged in parallel in the third direction D3. Here, the first source/drain area 151 may contact each of the plurality of first nano sheets NS1.

According to some example embodiments, the second source/drain area 152 may be located on at least one side of the second gate line 162 on the second active area F2. For example, a plurality of second source/drain areas 152 spaced apart from each other may be provided in the third direction D3. A pair of second source/drain areas 152 may be arranged on both sides of the second gate line 162 on the second active area F2 in the third direction D3. Further, the second source/drain areas 152 may be arranged between a plurality of second nano sheet stacks NSS2 arranged in parallel in the third direction D3. Here, the second source/drain area 152 may contact each of the plurality of second nano sheets NS2.

In some example embodiments, the first source/drain area 151 and the second source/drain area 152 may be p-type source/drain areas doped with p-type impurities. For example, the p-type impurity may include at least one of the elements boron (B), aluminum (Al), gallium (Ga), and/or indium (In). Therefore, the plurality of first source/drain areas 151, the first gate line 161, and the first nano sheet stack NSS1 may form a PMOS transistor. The plurality of second source/drain areas 152, the second gate lines 162, and the second nano sheet stack NSS2 may also form PMOS transistors.

According to some example embodiments, the third source/drain area 251 may be located on at least one side of the third gate line 261 on the third active area F3. For example, a plurality of third source/drain areas 251 spaced apart from each other may be provided in the third direction D3. A pair of third source/drain areas 251 may be arranged on both sides of the third gate line 261 on the third active area F3 in the third direction D3. Further, the third source/drain area 251 may be arranged between a plurality of third nano sheets stack NSS3 arranged in parallel in the third direction D3. Here, the third source/drain areas 251 may contact each of the plurality of third nano sheets NS3.

According to some example embodiments, the fourth source/drain area 252 may be located on at least one side of the fourth gate line 262 on the fourth active area F4. For example, a plurality of fourth source/drain areas 252 spaced apart may be provided in the third direction D3. A pair of fourth source/drain areas 252 may be placed on both sides of the fourth gate line 262 in the third direction D3 on the fourth active area F4. Further, the fourth source/drain area 252 may be arranged between a plurality of fourth nano sheets stack NSS4 arranged in parallel in the third direction D3. Here, the fourth source/drain area 252 may contact each of the plurality of fourth nano sheets NS4.

According to some example embodiments, the plurality of source/drain areas (the first source/drain area 151, the second source/drain area 152, the third source/drain area 251, and the fourth source/drain area 252) located in the third direction D3 from the plurality of nano sheets (the first nano sheet NS1 to the fourth nano sheet NS4) cover the plurality of nano sheets (the first nano sheet NS1 to the fourth nano sheet NS4) in the second direction D2. Therefore, the widths W6 of the first source/drain area 151 and the second source/drain area 152 in the second direction D2 are also proportional to a first width W1 of the first nano sheet NS1 and the second nano sheet NS2. The widths W7 of the third source/drain area 251 and the fourth source/drain area 252 in the second direction D2 are also proportional to the second width W2 of the third nanosheet NS1 and the fourth nano sheet NS4. In other words, the longest width of the first source/drain area 151 and the second source/drain area 152 in the second direction D2 may be greater than the longest width of the third source/drain area 251 and the fourth source/drain area 252 in the second direction D2.

In some example embodiments, the third source/drain area 251 and the fourth source/drain area 252 may be n-type source/drain areas doped with n-type impurities. For example, the n-type impurity may include at least one of the elements phosphorus (P), arsenic (As), and/or antimony (Sb). Therefore, the plurality of third source/drain areas 251, the third gate line 261, and the third nano sheet stack NSS3 may form an NMOS transistor. The plurality of fourth source/drain areas 252, the fourth gate lines 262, and the fourth nano sheet stack NSS4 may also form NMOS transistors.

According to some example embodiments, the plurality of gate cuts (the first gate cut GC1 to the third gate cut GC3) may be arranged at the ends of each of the plurality of gate lines (the first gate line 161, the second gate line 162, the third gate line 261, and the fourth gate line 262) in the second direction D2 on the substrate 100 and the plurality of field insulating films (the first field insulating film 105 to the third field insulating film 107). For example, an upper surface of the plurality of gate cuts (the first gate cut GC1 to the third gate cut GC3) may be formed on the same plane as the upper surface of the capping pattern 166. For example, the lower surface of the plurality of gate cuts (the first gate cut GC1 to the third gate cut GC3) may be formed inside the plurality of field insulating films (the first field insulating film 105 to the third field insulating film 107). However, the technical idea of the present disclosure is not limited thereto. In some other example embodiments, the lower surface of the plurality of gate cuts (the first gate cut GC1 to the third gate cut GC3) may contact the upper surface of the field insulating films (the first field insulating film 105 to the third field insulating film 107).

According to some example embodiments, the plurality of gate cuts (the first gate cut GC1 to the third gate cut GC3) may include the first gate cut GC1, the second gate cut GC2, and the third gate cut GC3 arranged in parallel in the second direction D2. The first gate cut GC1 may be placed at the end of the first gate line 161, and the second gate cut GC2 may be intervened between the second gate line 162 and the third gate line 261. The third gate cut GC3 may be placed at the end of the fourth gate line 262. According to some example embodiments, the distance between the first gate cut GC1 and the second gate cut GC2 is equal to the distance between the second gate cut GC2 and the third gate cut GC3. For the integrated circuit device 10 according to some example embodiments, the distance from the center of the first gate cut GC1 to the center of the third gate cut GC3 may be defined as the unit cell height. The cells constituting the semiconductor device including the integrated circuit device 10 may each have the same cell height. As will be described later, within the unit cell height, the spacing distance between the first gate cut GC1 and the second gate cut GC2 is equal to the spacing distance between the second gate cut GC2 and the third gate cut GC3, and thus, as the width of the first insulating pillar 110 decreases, the widths of the first nano sheet NS1 and the second nano sheet NS2 increase, and as the width of the second insulating pillar 210 increases, the widths of the third nano sheet NS3 and the fourth nano sheet NS4 decrease.

According to some example embodiments, the plurality of gate cuts (the first gate cut GC1 to the third gate cut GC3) may include, for example, one of silicon nitride (SiN), silicon oxynitride (SiON), silicon oxide (SiO2), silicon oxycarbonitride (SiOCN), and/or a combination thereof. However, the technical idea of the present disclosure is not limited thereto.

According to some example embodiments, a first gate dielectric film 141 may be interposed between the first gate line 161 and the plurality of first nano sheets NS1. The first gate dielectric film 141 may be interposed between the first gate line 161 and the first source/drain area 151. The first gate dielectric film 141 may be interposed between the first gate line 161 and the first active area F1. The first gate dielectric film 141 may be interposed between the first gate line 161 and the first field insulating film 105. The first gate dielectric film 141 may be interposed between the first gate line 161 and the first gate cut GC1. The first gate dielectric film 141 may be interposed between the first gate line 161 and the first filling film 111.

According to some example embodiments, a second gate dielectric film 142 may be interposed between the second gate line 162 and the plurality of second nano sheets NS2. The second gate dielectric film 142 may be interposed between the second gate line 162 and the second source/drain area 152. The second gate dielectric film 142 may be interposed between the second gate line 162 and the second active area F2. The second gate dielectric film 142 may be interposed between the second gate line 162 and the second field insulating film 106. The second gate dielectric film 142 may be interposed between the second gate line 162 and the second gate cut GC2. The second gate dielectric film 142 may be interposed between the second gate line 162 and the first filling film 111.

According to some example embodiments, a third gate dielectric film 241 may be interposed between the third gate line 261 and the plurality of third nano sheets NS3. The third gate dielectric film 241 may be interposed between the third gate line 261 and the third source/drain area 251. The third gate dielectric film 241 may be interposed between the third gate line 261 and the third active area F3. The third gate dielectric film 241 may be interposed between the third gate line 261 and the second field insulating film 106. The third gate dielectric film 241 may be interposed between the third gate line 261 and the second gate cut GC2. The third gate dielectric film 241 may be interposed between the third gate line 261 and the second filling film 211.

According to some example embodiments, the fourth gate dielectric film 242 may be interposed between the fourth gate line 262 and the plurality of fourth nano sheets NS4. The fourth gate dielectric film 242 may be interposed between the fourth gate line 262 and the fourth source/drain area 252. The fourth gate dielectric film 242 may be interposed between the fourth gate line 262 and the fourth active area F4. The fourth gate dielectric film 242 may be interposed between the fourth gate line 262 and the third field insulating film 107. The fourth gate dielectric film 242 may be interposed between the fourth gate line 262 and the third gate cut GC3. The fourth gate dielectric film 242 may be interposed between the fourth gate line 262 and the second filling film 211.

According to some example embodiments, each of the first gate dielectric film to the fourth gate dielectric film 242 may include at least one of silicon oxide, silicon oxynitride, silicon nitride, and/or a high-k material having a dielectric constant greater than silicon oxide. The high-k material may include one or more of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and/or lead zinc niobate.

The integrated circuit device 10 according to some other example embodiments may include a negative capacitance (NC) FET using a negative capacitor. For example, each of the first gate dielectric film 141 and the second gate dielectric film 142 may include a ferroelectric material film having ferroelectric properties and a paraelectric material film having paraelectric properties.

According to some example embodiments, the ferroelectric material film may have negative capacitance, and a paraelectric material film may have positive capacitance. For example, when two or more capacitors are connected in series and the capacitance of each capacitor has a positive value, the overall capacitance is reduced compared to the capacitance of each individual capacitor. On the other hand, when at least one of the capacitances of two or more capacitors connected in series has a negative value, the total capacitance may be positive and greater than the absolute value of each individual capacitance.

According to some example embodiments, when a ferroelectric material film with negative capacitance and a paraelectric material film with positive capacitance are connected in series, the overall capacitance value of the ferroelectric material films and paraelectric material films connected in series may increase. By taking advantage of the increase in the overall capacitance value, the transistor containing the ferroelectric material film may have a subthreshold swing (SS) of less than 60 mV/decade at room temperature.

According to some example embodiments, the ferroelectric material film may have ferroelectric properties. The ferroelectric material film may include at least one of, for example, hafnium oxide, hafnium zirconium oxide, barium strontium titanium oxide, barium titanium oxide, and/or lead zirconium titanium oxide. Here, for example, hafnium zirconium oxide may be a material in which zirconium (Zr) is doped into hafnium oxide. For another example, the hafnium zirconium oxide may be a compound of hafnium (Hf), zirconium (Zr), and oxygen (O).

According to some example embodiments, the ferroelectric material film may further contain doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). Depending on what kind of ferroelectric material the ferroelectric material film contains, the type of dopant contained in the ferroelectric material film may vary.

According to some example embodiments, when the ferroelectric material film includes hafnium oxide, the dopant included in the ferroelectric material film may include at least one of, for example, gadolinium (Gd), silicon (Si), zirconium (Zr), aluminum (Al), and/or yttrium (Y).

According to some example embodiments, when the dopant is aluminum (Al), the ferroelectric material film may contain 3 to 8 at % (atomic %) of aluminum. Here, the ratio of the dopant may be the ratio of aluminum to the sum of hafnium and aluminum.

According to some example embodiments, when the dopant is silicon (Si), the ferroelectric material film may contain 2 to 10 at % of silicon. When the dopant is yttrium (Y), the ferroelectric material film may contain 2 to 10 at % of yttrium. When the dopant is gadolinium (Gd), the ferroelectric material film may contain 1 to 7 at % of gadolinium. When the dopant is zirconium (Zr), the ferroelectric material film may contain 50 to 80 at % of zirconium.

According to some example embodiments, the paraelectric material film may have paraelectric properties. The paraelectric material film may include, for example, at least one of silicon oxide and a metal oxide having a high dielectric constant. The metal oxide included in the paraelectric material film may include, for example, at least one of hafnium oxide, zirconium oxide, and/or aluminum oxide, but the present disclosure is not limited thereto.

According to some example embodiments, the ferroelectric material film and the paraelectric material film may contain the same material. The ferroelectric material film may have ferroelectric properties, but the paraelectric material film may not have ferroelectric properties. For example, when the ferroelectric material film and paraelectric material film contain hafnium oxide, the crystal structure of hafnium oxide included in the ferroelectric material film is different from the crystal structure of hafnium oxide included in the paraelectric material film.

According to some example embodiments, the ferroelectric material film may have a thickness that exhibits ferroelectric properties. The thickness of the ferroelectric material film may be, for example, 0.5 to 10 nm, but the ferroelectric material film is not limited thereto. The threshold thickness for exhibiting ferroelectric properties may vary for each ferroelectric material, and thus the thickness of the ferroelectric material film may vary depending on the ferroelectric material.

In some example embodiments, each of the first gate dielectric film 141 to the fourth gate dielectric film 242 may include one ferroelectric material film. In another example embodiment, each of the first gate dielectric film 141 to the fourth gate dielectric film 242 may include a plurality of ferroelectric material films spaced apart from each other. Each of the first gate dielectric film 141 to the fourth gate dielectric film 242 may have a laminated film structure in which a plurality of ferroelectric material films and a plurality of paraelectric material films are alternately laminated.

According to some example embodiments, the capping pattern 166 may be arranged on the plurality of gate lines (the first gate line 161, the second gate line 162, the third gate line 261, and the fourth gate line 262) in the second direction D2 and/or the third direction D3. The capping pattern 166 may contact the upper surface of the plurality of gate lines (the first gate line 161, the second gate line 162, the third gate line 261, and the fourth gate line 262). However, the technical idea of the present disclosure is not limited thereto. The capping pattern 166 may include, for example, at least one of silicon nitride (SiN), silicon oxynitride (SiON), silicon oxide (SiO2), silicon carbonitride (SiCN), silicon oxycarbonitride (SiOCN), and/or combinations thereof.

According to some example embodiments, although not depicted in detail in the drawing, an inner insulating spacer (not illustrated) may be provided between the plurality of first nano sheets NS1 and the plurality of second nano sheets NS2 that serve as channels of the PMOS transistor. The inner insulating spacer (not illustrated) may also be located between the first active area and the second active area F2 and the lowermost first nano sheet NS1 and second nano sheet NS2.

According to some example embodiments, a first upper filling film 124 may be interposed between the first insulating cap 123 and the first upper insulting pillar 130, and a second upper filling film 224 may be interposed between the second insulating cap 223 and the second upper insulting pillar 230. The first upper filling film 124 and the second upper filling film 224 may include the same materials as the first barrier 121 to the fourth barrier 222, the first insulating liner 112, and the second insulating liner 212.

According to some example embodiments, a gate spacer 185 may be extended on both side walls of the first gate line 161 in the second direction D2. The gate spacer 185 may be placed on both side walls of the first gate line 161 on the uppermost first nano sheet NS1. Although not depicted in detail in the drawing, the gate spacer 185 may be extended in the second direction D2 on both side walls of the first gate line 161 as well as the second gate line 162 to the fourth gate line 262.

According to some example embodiments, the gate spacer 185 may include, for example, at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and/or combinations thereof.

According to some example embodiments, the first interlayer insulating film 180 may be disposed on the first field insulating film 105 to the third field insulating film 107. The first interlayer insulating film 180 may surround each of the first source/drain area 151 to the fourth source/drain area 252. The first interlayer insulating film 180 may surround a side wall of each of the first gate line to the fourth gate line (the first gate line 161, the second gate line 162, the third gate line 261, and the fourth gate line 262), the first upper insulting pillar and the second upper insulting pillar 230, and the first source/drain contact CA1 to the fourth source/drain contact CA4 on the first source/drain area 151 to the fourth source/drain area 252. For example, the upper surface of the first interlayer insulating film 180 may be formed on the same plane as the upper surfaces of the first upper insulting pillar and the second upper insulting pillar 230.

According to some example embodiments, the first interlayer insulating film 180 may include, for example, at least one of silicon oxide, silicon nitride, silicon oxynitride, and/or a low-k material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, and/or a combination thereof. However, the technical idea of the present disclosure is not limited thereto.

According to some example embodiments, the plurality of source/drain contacts (the first source/drain contact CA1 to the fourth source/drain contact CA4) may be connected to the plurality of source/drain areas (the first source/drain area 151, the second source/drain area 152, the third source/drain area 251, and the fourth source/drain area 252) by penetrating the first interlayer insulating film 180 in the first direction D1. For example, at least a portion of the first source/drain contact CA1 may extend into the interior of the first source/drain area 151. Likewise, at least a portion of a second source/drain contact CA2 to at least a portion of the fourth source/drain contact CA4 may extend into the interior of the second source/drain area 152 to the fourth source/drain area 252.

For example, the upper surface of the first source/drain contact CA1 may be formed on the same plane as the upper surface of the first interlayer insulating film 180. However, the technical idea of the present disclosure is not limited thereto. Even though FIG. 4 illustrates that the plurality of source/drain contacts (the first source/drain contact CA1 to the fourth source/drain contact CA4) are formed in a single film, it is for convenience of explanation and the technical idea of the present disclosure is not limited thereto. In other words, the plurality of source/drain contacts (the first source/drain contact CA1 to the fourth source/drain contact CA4) may be formed as plurality of layers. The plurality of source/drain contacts (the first source/drain contact CA1 to the fourth source/drain contact CA4) may contain a conductive material. The above description is not limited to the first source/drain contact CA1, but may also be applied to the second source/drain contact CA2 to the fourth source/drain contact CA4. In other words, the upper surface of the second source/drain contact CA2 to the fourth source/drain contact CA4 may be formed on the same plane as the upper surface of the first interlayer insulating film 180.

According to some example embodiments, the first silicide layer 171 may be placed between the first source/drain area 151 and the first source/drain contact CA1. Similarly, a second silicide layer 172 to the fourth silicide layer 272 may be placed between the second source/drain area 152 to the fourth source/drain area 252 and the second source/drain contact CA2 to the fourth source/drain contact CA4. The first silicide layer 171 to the fourth silicide layer 272 may, for example, include a metal silicide material.

According to some example embodiments, the first gate contact CB1 may be connected to the first gate line 161 by penetrating the capping pattern 166 in the first direction D1. Similarly, the second to fourth gate contacts CB4 may be connected to the second gate line 162 to the fourth gate line 262 by penetrating the capping pattern 166 in the first direction D1.

For example, the upper surface of the first gate contact CB1 to the fourth gate contact CB4 may be formed on the same plane as the upper surface of the capping pattern 166. However, the technical idea of the present disclosure is not limited thereto. Even though FIG. 2 illustrates the first gate contact CB1 to the fourth gate contact CB4 are formed as a single film, it is for convenience of explanation and the technical idea of the present disclosure is not limited thereto. In other words, the first gate contact CB1 to the fourth gate contact CB4 may be formed as plurality of layers. The first gate contact CB1 to the fourth gate contact CB4 may include conductive materials.

According to some example embodiments, the etching stopping film 191 may be disposed on the upper surface of each of the capping pattern 166, the first gate cut GC1 to the third gate cut GC3, the first gate contact CB1 to the fourth gate contact CB4, the first source/drain contact CA1 to the fourth source/drain contact CA4, the first upper insulting pillar 130, and the second upper insulting pillar 230. The etching stopping film 191, for example, may be formed conformally. Even though FIG. 2, FIG. 4 and FIG. 5 illustrate that the etching stopping film 191 is formed as a single film, the technical idea of the present disclosure is not limited thereto. In some other example embodiments, the etching stopping film 191 may be formed as plurality of layers. The etching stopping film 191 may include, for example, at least one of aluminum oxide, aluminum nitride, hafnium oxide, zirconium oxide, silicon oxide, silicon nitride, silicon oxynitride, and/or a low-k material.

According to some example embodiments, the second interlayer insulating film 192 may be disposed on the etching stopping film 191. The second interlayer insulating film 192 may include, for example, at least one of silicon oxide, silicon nitride, silicon oxynitride, and/or a low-k material.

According to some example embodiments, the first via V1 to a fourth via V4 may penetrate the second interlayer insulating film 192 and the etching stopping film 191 in the first direction D1 and be connected to the plurality of gate contacts (the first gate contact CB1 to the fourth gate contact CB4). The first via V1 may be connected to the first gate contact CB1, and a second via V2 may be connected to a second gate contact CB2. A third via V3 may be connected to a third gate contact CB3, and the fourth via V4 may be connected to the fourth gate contact CB4. Even though FIG. 2 illustrates that the first via V1 to the fourth via V4 are formed as a single film, it is for convenience of explanation and the technical idea of the present disclosure is not limited thereto. In some other example embodiments, the first via V1 to the fourth via V4 may be formed as plurality of layers.

According to some example embodiments, a fifth via V5 to the eighth via V8 may penetrate the second interlayer insulating film 192 and the etching stopping film 191 in the first direction D1 and be connected to the plurality of source/drain contacts (the first source/drain contact CA1 to the fourth source/drain contact CA4). The fifth via V5 may be connected to the first source/drain contact CA1, and a sixth via V6 may be connected to the second source/drain contact CA2. A seventh via V7 may be connected to a third source/drain contact CA3, and the eighth via V8 may be connected to the fourth source/drain contact CA4. Even though FIG. 4 illustrates that the fifth via V5 to the eighth via V8 are formed as a single film, it is for convenience of explanation and the technical idea of the present disclosure is not limited thereto. In some other example embodiments, the fifth via V5 to the eighth via V8 may be formed in a plurality of layers. The fifth via V5 to the eighth via V8 may contain conductive material.

According to some example embodiments, each of the first nano sheet NS1 and the second nano sheet NS2 may have the first width W1 in the second direction D2. Each of the third nano sheet NS3 and the fourth nano sheet NS4 may have a second width W2 in the second direction D2. The width of each of the first active area F1 to the fourth active area F4 in the second direction D2 may correspond to the width of each of the first nano sheet to the fourth nano sheet NS4 in the second direction D2. Therefore, the first active area F1 and the second active area F2 may have the first width W1 in the second direction D2, and the third active area F3 and the fourth active area F4 may have the second width W2 in the second direction D2.

According to some example embodiments, each of the plurality of field insulating films (the first field insulating film 105 to the third field insulating film 107) may have the same third width W3 in the second direction D2. The first insulating pillar 110 may have the fourth width W4 in the second direction D2, and the second insulating pillar 210 may have the fifth width W5 in the second direction D2. Since FIG. 1 and FIG. 2 illustrate only half portion of the first field insulating film 105 and only half portion of the third field insulating film 107, the width of the first field insulating film 105 and the third field insulating film 107 in the second direction D2 was expressed as half of the third width (W3_H).

As described earlier, the distance between the first gate cut GC1 and the second gate cut GC2 is equal to the distance between the second gate cut GC2 and the third gate cut GC3. Therefore, in some example embodiments, the sum of the first widths W1 of each of the first nano sheet NS1 and the second nano sheet NS2 and the sum of the fourth width W4 of the first insulating pillar 110 may be equal to the sum of the second widths W2 of each of the third nano sheet NS3 and the fourth nano sheet NS4 and the sum of the fifth width W5 of the second insulating pillar 210. When the fourth width W4 of the first insulating pillar 110 is smaller than the fifth width W5 of the second insulating pillar 210, the first width W1 of each of the first nano sheet NS1 and the second nano sheet NS2 becomes larger than the second width W2 of each of the third nano sheet NS3 and the fourth nano sheet NS4.

In some example embodiments, the carriers in the first source/drain area 151 and the second source/drain area 152 that make up the PMOS transistor are holes, and the carriers in the third source/drain area 251 and the fourth source/drain area 252 that make up the NMOS transistor are electrons. Since the mobility of electrons is more than twice the mobility of holes, the driving current flowing through the NMOS transistor may be greater than the driving current flowing through the PMOS transistor.

In some example embodiments, the first width W1 of the first nano sheet NS1 and the second nano sheet NS2, which serve as channels of the PMOS transistor, may be implemented to be larger than the second width W2 of the third nano sheet NS3 and the fourth nano sheet NS4, which serve as channels of the NMOS transistor, and thus a large number of holes may be provided in the first nano sheet NS1 and the second nano sheet NS2, which may improve the driving current of the PMOS transistor.

According to some example embodiments, when compressive stress is applied to the first nano sheet NS1 and the second nano sheet NS2, the mobility of holes in the first nano sheet NS1 and the second nano sheet NS2 may be improved. However, if the thickness of the first insulating pillar 110 interposed between the first nano sheet NS1 and the second nano sheet NS2 becomes relatively thicker, the stress applied to the first nano sheet NS1 and the second nano sheet NS2 may be distributed more. Therefore, by implementing the fourth width W4 of the first insulating pillar 110 to be smaller than the fifth width W5 of the second insulating pillar 210, the compressive stress may be applied more efficiently to the first nano sheet NS1 and the second nano sheet NS2, and thus the driving current of PMOS transistors may be improved.

In addition thereto, by implementing the second width W2 of the third nano sheet NS3 and the fourth nano sheet NS4, which serve as the channel of the NMOS transistor, to be small, the parasitic capacitance of NMOS transistors may be reduced. Therefore, since the second width W2 of the third nano sheet NS3 and the fourth nano sheet NS4 is implemented smaller than the first width W1 of the first nano sheet NS1 and the second nano sheet NS2, the parasitic capacitance of the integrated circuit device 10 may be reduced.

According to some example embodiments, the distance between the adjacent first field insulating film 105 and second field insulating film 106 is equal to the sum of the first width W1 of each of the first nano sheet NS1 and the second nano sheet NS2 and the fourth width W4 of the first insulating pillar 110. The distance between the adjacent second field insulating film 106 and third field insulating film 107 is equal to the sum of the second width W2 of each of the third nano sheet NS3 and the fourth nano sheet NS4 and the fifth width W5 of the second insulating pillar 210. While maintaining the distance between the first field insulating film 105 and the second field insulating film 106 and the distance between the second field insulating film 106 and the third field insulating film 107 to be equal, by making the thickness of the first insulating pillar 110 smaller than the thickness of the second insulating pillar 210, the driving current of PMOS transistors may be improved and the parasitic capacitance of NMOS transistors may be reduced.

Detailed explanations will be given below with the definition that when the first width W1 of the first nano sheet NS1 and the second nano sheet NS2 and the second width W2 of the third nano sheet NS3 and the fourth nano sheet NS4 are the same, the size of the transit frequency of an integrated circuit device is 100%. The effective resistance and effective capacitance of the integrated circuit device 10 begin to decrease when the first width W1 of the first nano sheet NS1 and the second nano sheet NS2 becomes larger than the second width W2 of the third nano sheet NS3 and the fourth nano sheet NS4. Then, when the value of the first width W1 compared to the second width W2 exceeds a certain value, the effective resistance and effective capacitance of the integrated circuit device 10 begin to increase again. The binge frequency size also begins to increase when the first width W1 becomes larger than the second width W2. Then, when the value of the first width W1 compared to the second width W2 exceeds a certain value, it becomes lower than the maximum value of the binge frequency, and eventually, the value of binge frequency becomes lower than 100%. Therefore, when the difference between the first width W1 of the first nano sheet NS1 and the second nano sheet NS2 in the second direction D2 and the second width W2 of the third nano sheet NS3 and the fourth nano sheet NS4 in the second direction D2 is in the range of 5% to 20% of the distance from the center of the first field insulating film 105 to the center of the third field insulating film 107, relative size of the above binge frequency exceeds 100%, and thus the binge frequency is improved. In some example embodiments, when the difference between the first width W1 and the second width W2 is in the range of 5% to 20% of the distance in the second direction D2 between a center axis of first field insulating film 105 extending in the first direction D1 and a center axis of the third field insulating film 107 extending in the first direction, relative size of the binge frequency exceeds 100%, and thus the binge frequency is improved.

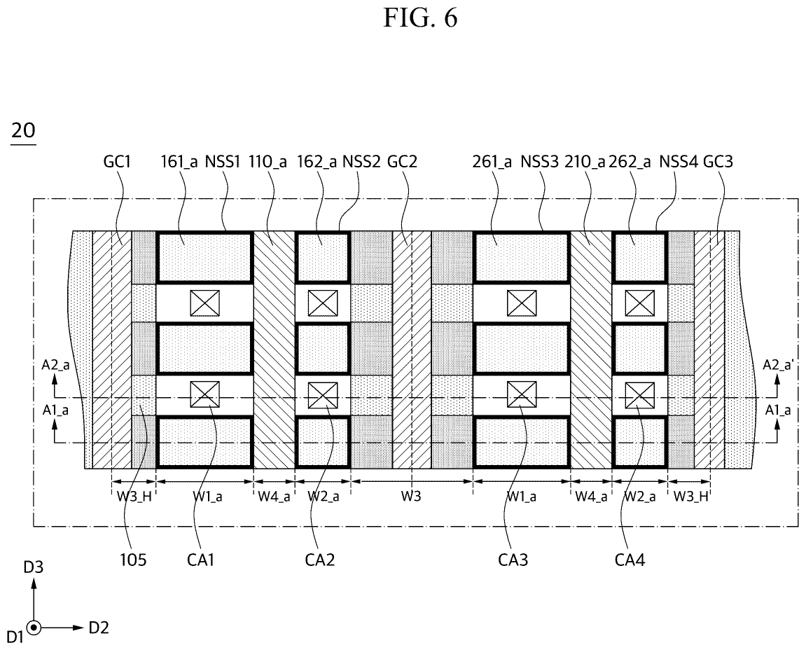

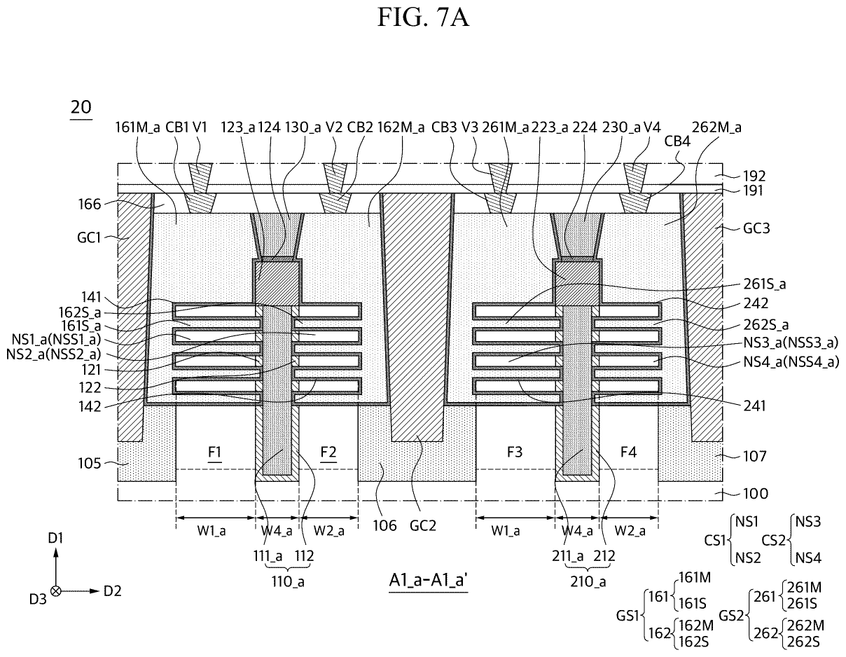

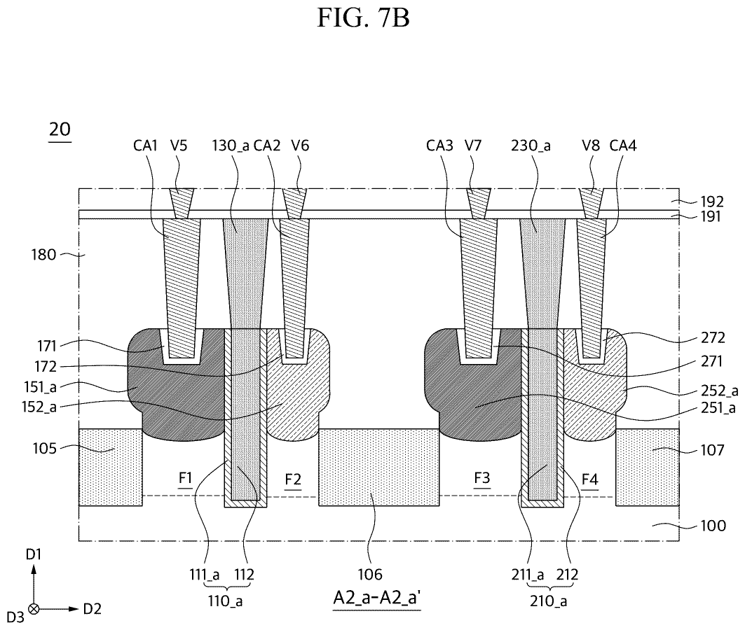

FIG. 6 is a planar layout diagram illustrating an integrated circuit device 20 according to some example embodiments of the technical idea of the present disclosure. FIG. 7A is a cross-sectional view taken along line A1_a-A1_a′ of FIG. 6. FIG. 7B is a cross-sectional view taken along line A2_a-A2_a′ of FIG. 6.

The integrated circuit device 20 illustrated in FIG. 6, FIG. 7A, and FIG. 7B is substantially equal or similar to the integrated circuit device 10 illustrated in FIG. 1 to FIG. 5, except for the types of carriers in a second source/drain area 152_a and a third source/drain area 251_a, a first insulating pillar 110_a and a second insulating pillar 210_a, the width of a second nano sheet NS2_a and a third nano sheet NS3_a, and the width of the second source/drain area 152_a and the third source/drain area 251_a. Hereinafter, explicitly described are differences from the integrated circuit device 10 illustrated in FIG. 1 to FIG. 5. The description of the components already described with reference to FIG. 1 to FIG. 5 is omitted.

Referring to FIG. 6, FIG. 7A and FIG. 7B, a first source/drain area 151_a and the third source/drain area 251_a are p-type source/drain areas where the carrier is hole, and the second source/drain area 152_a and a fourth source/drain area 252_a may be n-type source/drain areas where the carrier is electron.

According to some example embodiments, the width of a first nano sheet NS1_a in the second direction D2 and the width of the third nano sheet NS3_a in the second direction D2 may be equal to a first width W1_a, and the width of the second nano sheet NS2_a in the second direction D2 and the width of a fourth nano sheet NS4_a in the second direction D2 may be equal to a second width W2_a. Here, the first width W1_a may be larger than the second width W2_a.

According to some example embodiments, the plurality of source/drain areas (the first source/drain area 151_a, the second source/drain area 152_a, the third source/drain area 251_a, and the fourth source/drain area 252_a) located in the third direction D3 from the plurality of nano sheets (the first nano sheet NS1_a to the fourth nano sheet NS4_a) cover the plurality of nano sheets (the first nano sheet NS1_a to the fourth nano sheet NS4_a) in the second direction D2. Therefore, the widths of the first source/drain area 151_a and the third source/drain area 251_a in the second direction D2 are proportional to the first width W1_a of the first nano sheet NS1_a and the third nano sheet NS3_a. In other words, the longest width in the second direction D2 of the first source/drain area 151_a and the third source/drain area 251_a may be greater than the longest width in the second direction D2 of the second source/drain area 152_a and the fourth source/drain area 252_a.

According to some example embodiments, the width of the first insulating pillar 110_a located between the first field insulating film 105 and the second field insulating film 106 in the second direction D2 may be substantially equal to the width in the second direction D2 of the second insulating pillar 210_a located between the second field insulating film 106 and the third field insulating film 107.

According to some example embodiments, the distance between the adjacent first field insulating films 105 and second field insulating films 106 may be equal to the distance between the adjacent second field insulating film 106 and third field insulating film 107. The distance between the adjacent first field insulating film 105 and second field insulating film 106 is equal to the sum of the first width W1_a, the second width W2_a of each of the first nano sheet NS1_a and the second nano sheet NS2_a and a fourth width W4_a of the first insulating pillar 110_a. The distance between the adjacent second field insulating film 106 and third field insulating film 107 is equal to the sum of the first width W1_a, the second width W2_a of each of the third nano sheet NS3_a and the fourth nano sheet NS4_a and the fourth width W4_a of the second insulating pillar 210_a. The width of each of the first nano sheet NS1_a and the third nano sheet NS3_a is equal to the first width W1_a, and the width of each of the second nano sheet NS2_a and the fourth nano sheet NS4_a is equal to the second width W2_a, and thus the width of the first insulating pillar 110_a and the width of the second insulating pillar 210_a are also the same, with the fourth width W4_a.

According to some example embodiments, the thicknesses of the first insulating liner 112 and the second insulating liner 212 may be provided equally, and thus the widths of a first filling film 111_a and a second filling film 211_a in the second direction D2 may also be the same. Further, since the width of the first insulating pillar 110_a and the width of the second insulating pillar 210_a are the same, the widths of a first insulating cap 123_a and a second insulating cap 223_a in the second direction D2 may also be the same.

According to some example embodiments, the first insulating pillar 110_a may be positioned offset from the center of a distance between the adjacent first gate cut GC1 and second gate cut GC2 in the second direction D2. The distance between the first insulating pillar 110_a and the first gate cut GC1 in the second direction D2 may be different from the distance between the first insulating pillar 110_a and the second gate cut GC2. Similarly, the second insulating pillar 210_a may also be positioned offset from the center of a distance between the adjacent second gate cut GC2 and third gate cut GC3 in the second direction D2. The distance between the second insulating pillar 210_a and the second gate cut GC2 in the second direction D2 may be different from the distance between the second insulating pillar 210_a and the third gate cut GC3.

The integrated circuit device 20 illustrated in FIG. 6, FIG. 7A, and FIG. 7B may provide both NMOS transistors and PMOS transistors between a pair of adjacent gate cuts among the plurality of gate cuts (the first gate cut GC1 to the third gate cut GC3) spaced apart in the second direction D2.

As described with reference to FIG. 1 to FIG. 5, the first width W1_a of the first nano sheet NS1_a and the third nano sheet NS3_a, which serve as channels of the PMOS transistor, may be implemented to be larger than the second width W2_a of the second nano sheet NS2_a and the fourth nano sheet NS4_a, which serve as channels of the NMOS transistor. Thus, since many holes are provided in the first nano sheet NS1_a and the third nano sheet NS3_a, the driving current of the PMOS transistor may be improved. Both NMOS and PMOS transistors may be provided in the space between each of the plurality of gate cuts (the first gate cut GC1, the second gate cut GC2 and the third gate cut GC3), and thus the integration level may be improved.

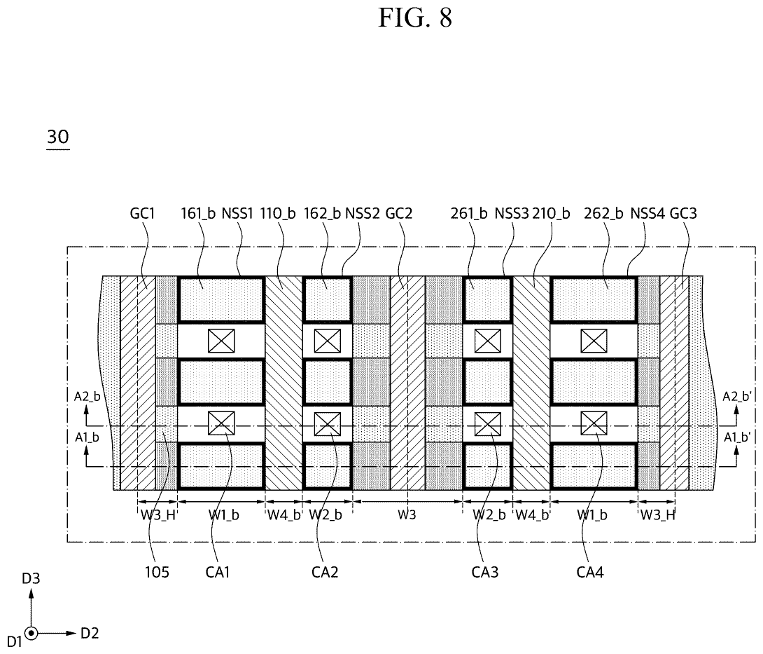

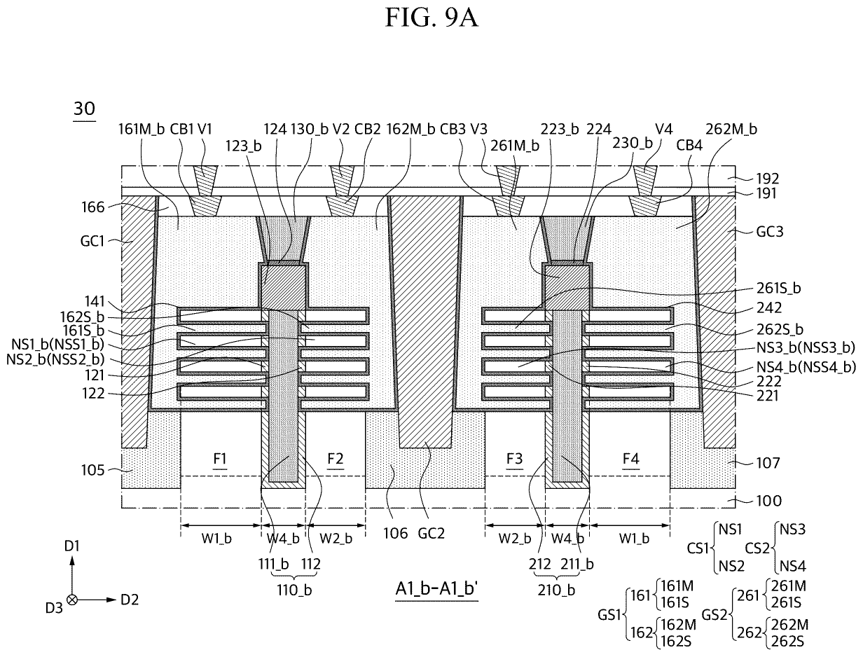

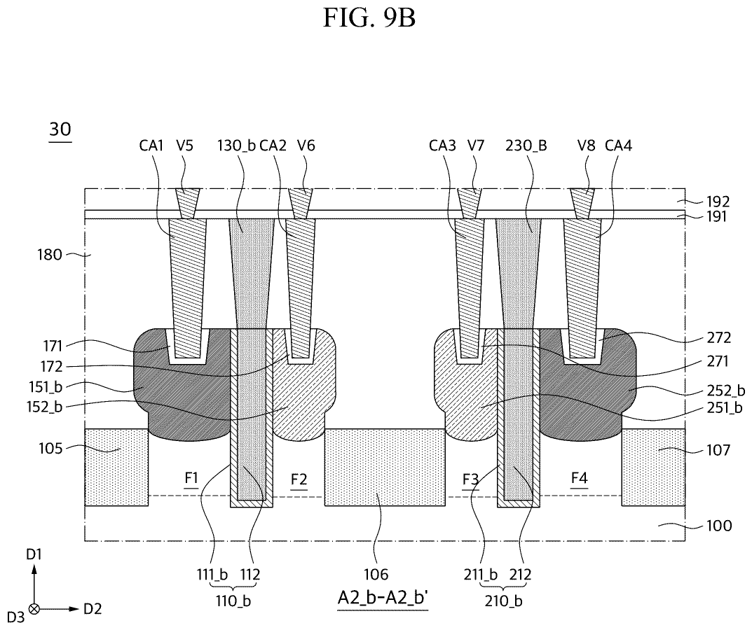

FIG. 8 is a planar layout diagram illustrating an integrated circuit device 30 according to some example embodiments of the technical idea of the present disclosure. FIG. 9A is a cross-sectional view taken along line A1_b-A1_b′ of FIG. 8. FIG. 9B is a cross-sectional view taken along line A2_b-A2_b′ of FIG. 6.

The integrated circuit device 30 illustrated in FIG. 8, FIG. 9A, and FIG. 9B is substantially equal or similar to the integrated circuit device 10 illustrated in FIG. 1 to FIG. 5, except for the types of carriers in a second source/drain area 152_b and a fourth source/drain area 252_b, the width of a first insulating pillar 110_b and a second insulating pillar 210_b, the width of a second nano sheet NS2_b and a fourth nano sheet NS4_b, and the width of the second source/drain area 152_b and the fourth source/drain area 252_b. Explicitly described below are differences from the integrated circuit device 10 illustrated in FIG. 1 to FIG. 5, and the description of the components already mentioned with reference to FIG. 1 to FIG. 5 is omitted.

Referring to FIG. 8, FIG. 9A, and FIG. 9B, a first source/drain area 151_b and the fourth source/drain area 252_b are p-type source/drain areas where the carrier may be hole, and the second source/drain area 152_b and a third source/drain area 251_b may be n-type source/drain areas where the carrier may be electron.

According to some example embodiments, the width of a first nano sheet NS1_b in the second direction D2 and the width of the fourth nano sheet NS4_b in the second direction D2 may be equal to a first width W1_b, and the width of the second nano sheet NS2_b in the second direction D2 and the width of a third nano sheet NS3_b in the second direction D2 may be equal to a second width W2_b. Here, the first width W1_b may be larger than the second width W2_b.

According to some example embodiments, the plurality of source/drain areas 151_b, 152_b, 251_b and 252_b located in the third direction D3 from the plurality of nano sheets (the first nano sheet NS1_b to the fourth nano sheet NS4_b) cover the plurality of nano sheets (the first nano sheet NS1_b to the fourth nano sheet NS4_b) in the second direction D2. Therefore, the width of the first source/drain area 151_b and the fourth source/drain area 252_b in the second direction D2 is also proportional to the first width W1_b of the first nano sheet NS1_b and the fourth nano sheet NS4_b. In other words, the longest width of the first source/drain area 151_b and the fourth source/drain area 252_b in the second direction D2 may be greater than the longest width in the second direction D2 of the second source/drain area 152_b and the third source/drain area 251_b.

According to some example embodiments, the width the first insulating pillar 110_b located between the first field insulating film 105 and the second field insulating film 106 in the second direction D2 may be substantially equal to the width in the second direction D2 of the second insulating pillar 210_b located between the second field insulating film 106 and the third field insulating film 107.

According to some example embodiments, the distance between the adjacent first field insulating films 105 and second field insulating films 106 may be equal to the distance between the adjacent second field insulating film 106 and third field insulating film 107. The distance between the adjacent first field insulating film 105 and second field insulating film 106 may be equal to the sum of the first width W1_b of the first nano sheet NS1_b, the second width W2_b of the second nano sheet NS2_b, and a fourth width W4_b of the first insulating pillar 110_b. The distance between the adjacent second field insulating film 106 and third field insulating film 107 may be equal to the sum of the second width W2_b of the third nano sheet NS3_b, the first width W1_b of the fourth nano sheet NS4_b, and the fourth width W4_b of the second insulating pillar 210_b. The width of each of the first nano sheet NS1_b and the fourth nano sheet NS4_b is equal to the first width W1_b, and the width of each of the second nano sheet NS2_b and the third nano sheet NS3_b is equal to the second width W2_b, and thus the width of the first insulating pillar 110_b and the width of the second insulating pillar 210_b are also the same, as the fourth width W4_b.

According to some example embodiments, the thicknesses of the first insulating liner 112 and the second insulating liner 212 may be provided equally, and thus the widths of a first filling film 111_b and a second filling film 211_b in the second direction D2 may also be the same. Further, since the width of the first insulating pillar 110_b and the width of the second insulating pillar 210_b are the same, the widths of a first insulating cap 123_b and a second insulating cap 223_b in the second direction D2 may also be the same.

According to some example embodiments, the first insulating pillar 110_b may be positioned offset from the center between the adjacent first gate cut GC1 and second gate cut GC2 in the second direction D2. Similarly, the second insulating pillar 210_b may also be positioned offset from the center between the adjacent second gate cut GC2 and third gate cut GC3 in the second direction D2.

As described with reference to FIG. 1 to FIG. 5, since the first width W1_b of the first nano sheet NS1_b and the fourth nano sheet NS4_b, which serve as the channel of the PMOS transistor may be implemented to be larger than the second width W2_b of the second nano sheet NS2 and the third nano sheet NS3, which serve as the channel of the NMOS transistor, many holes may be provided in the first nano sheet NS1_b and the fourth nano sheet NS4_b. Thus, the driving current of PMOS transistors may be improved. Both NMOS and PMOS transistors may be provided in the space between each of the plurality of gate cuts (the first gate cut GC1, the second gate cut GC2 and the third gate cut GC3), and thus the integration level may be improved.

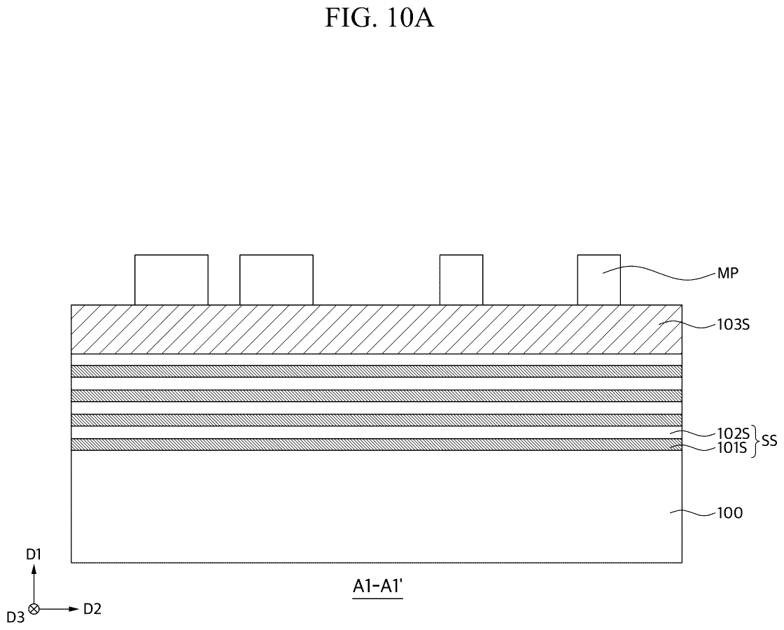

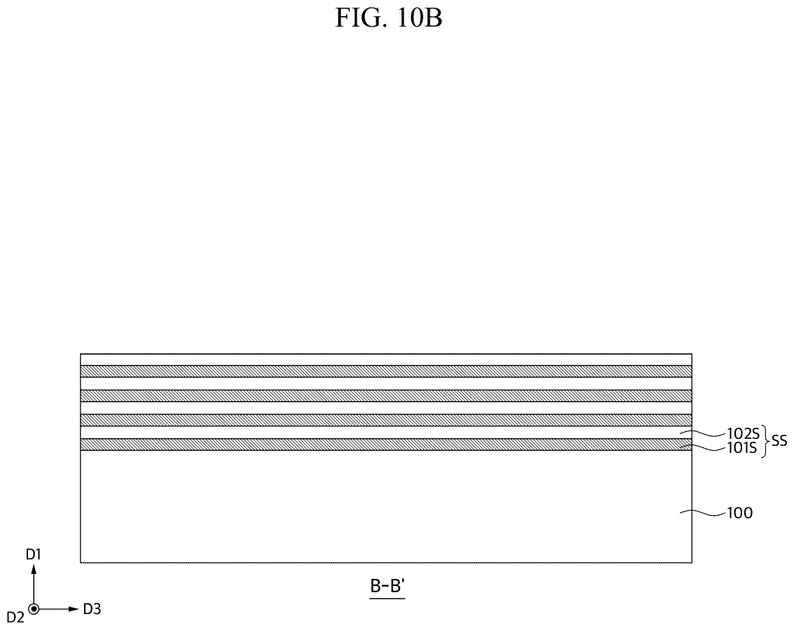

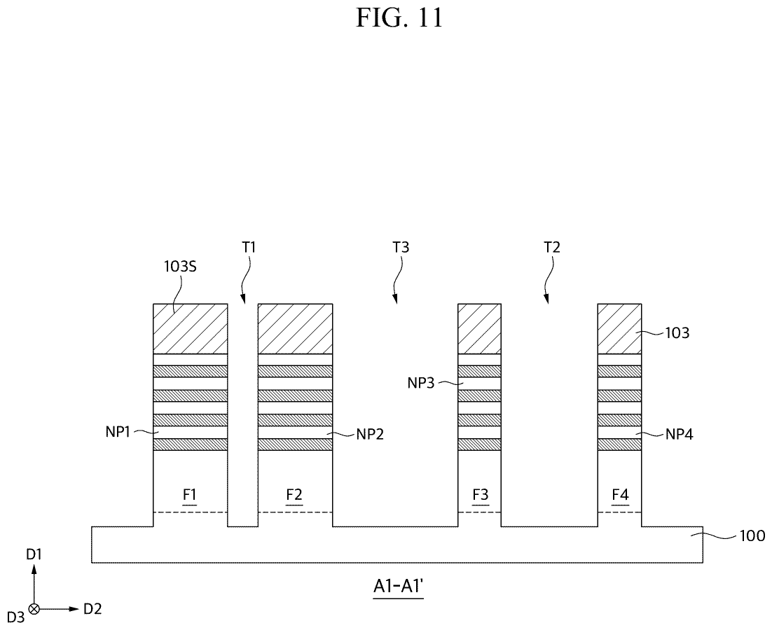

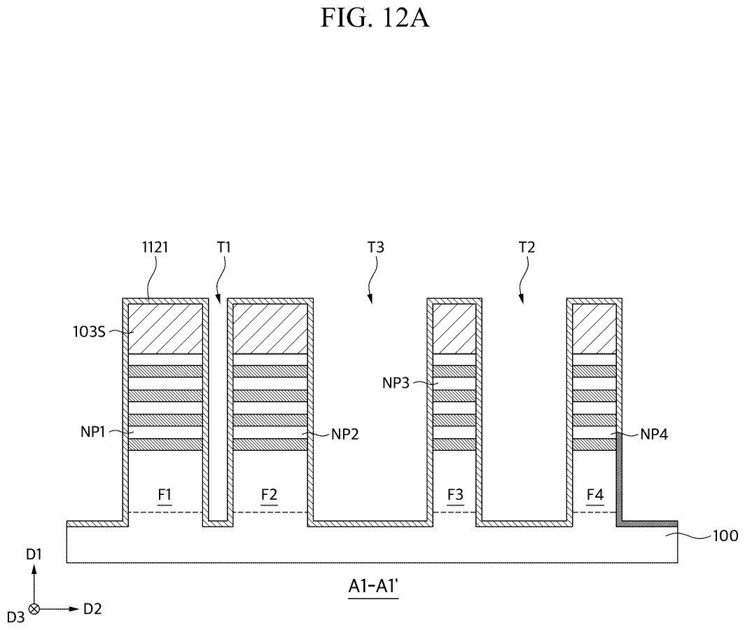

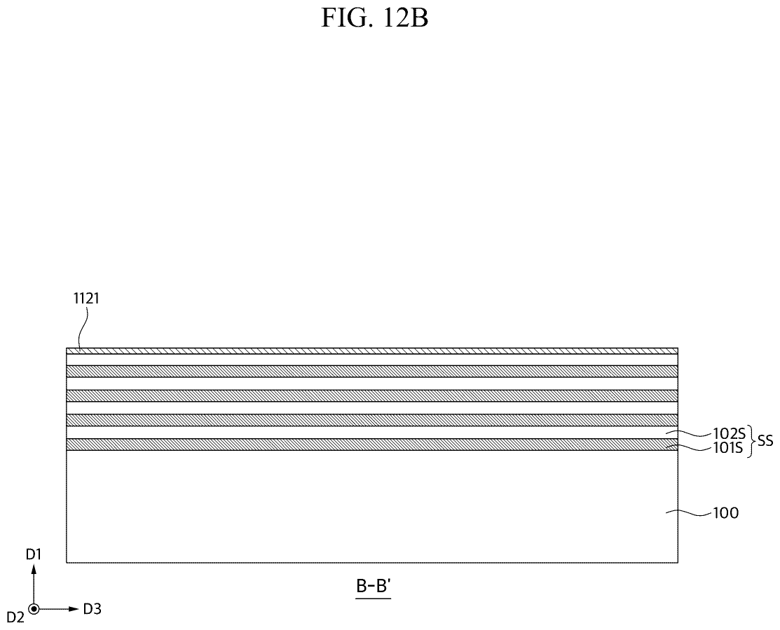

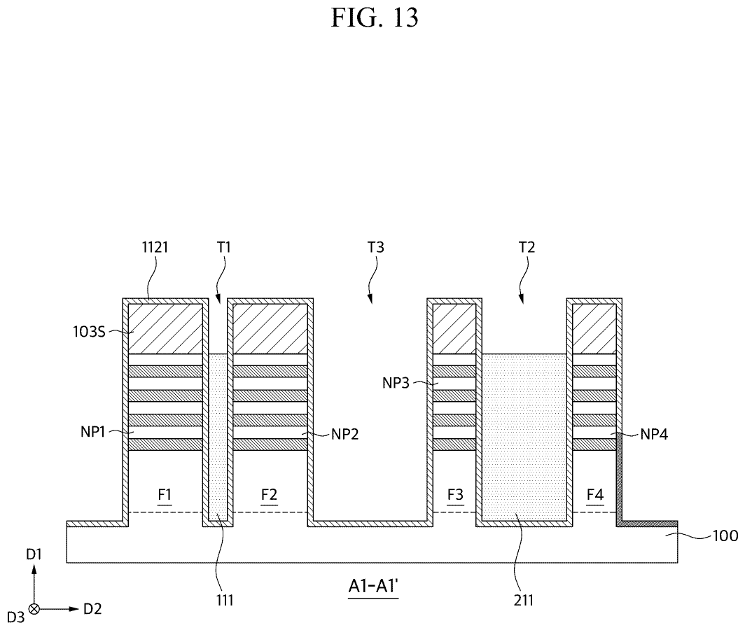

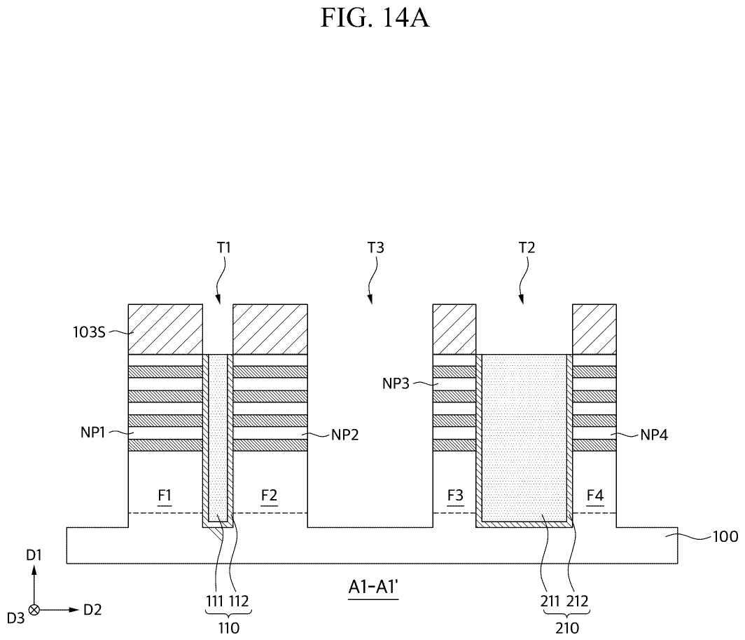

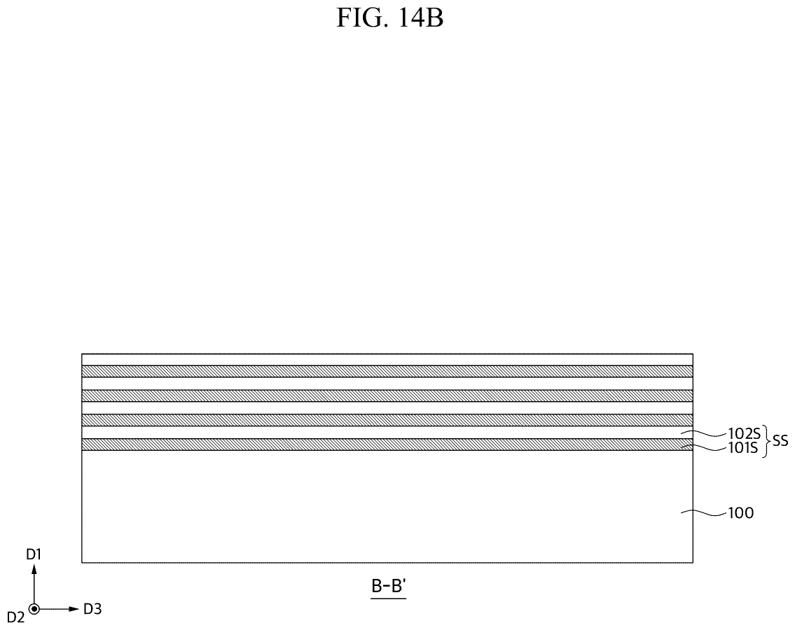

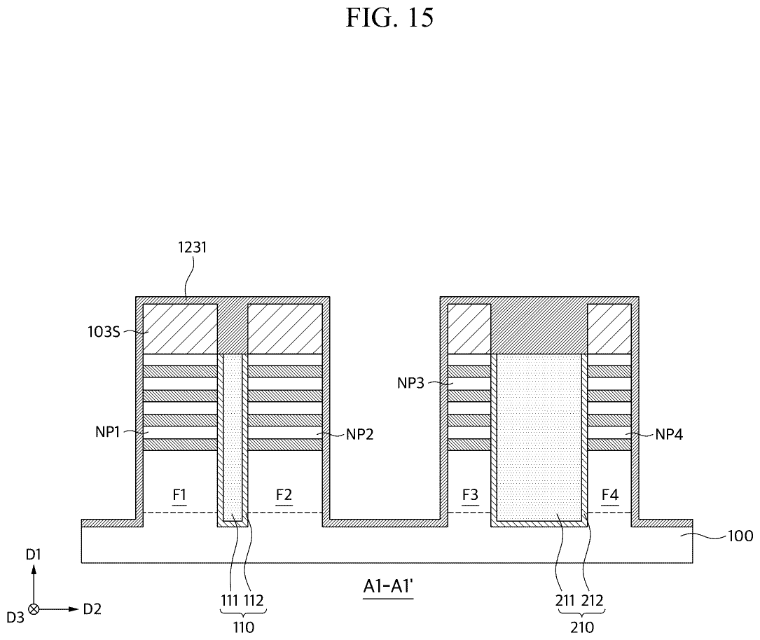

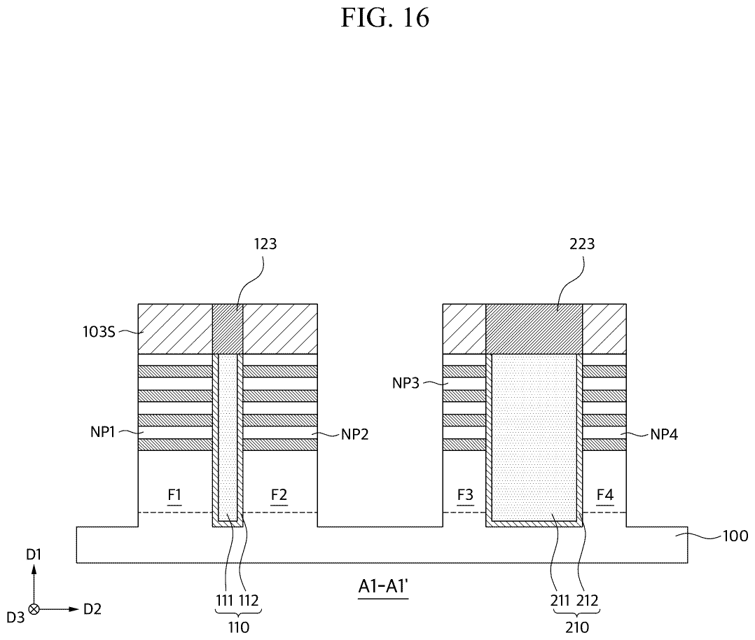

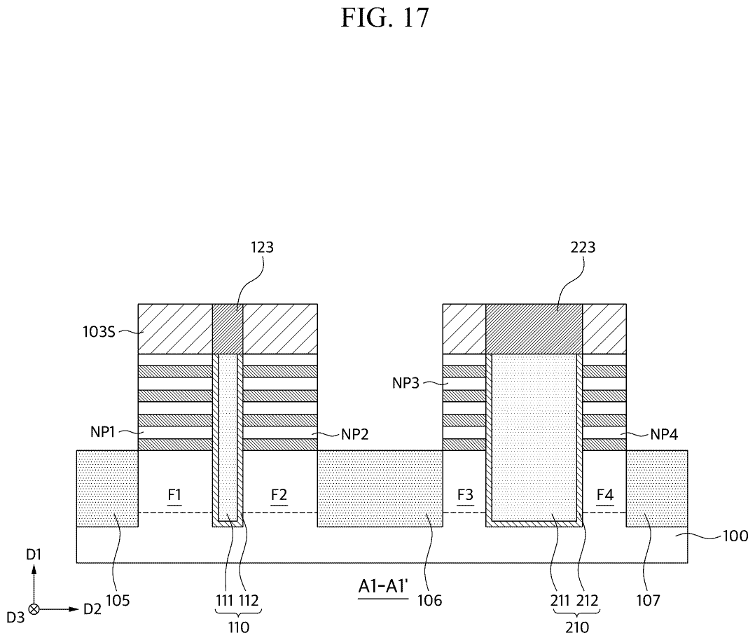

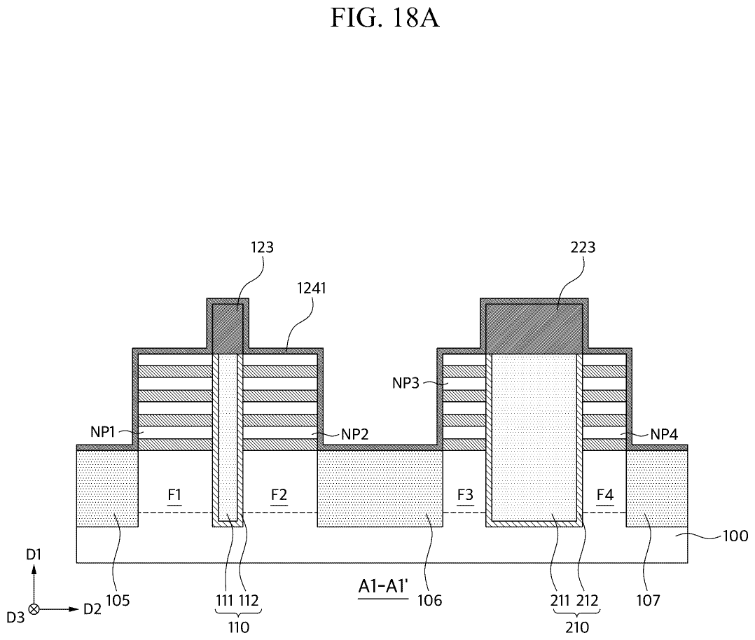

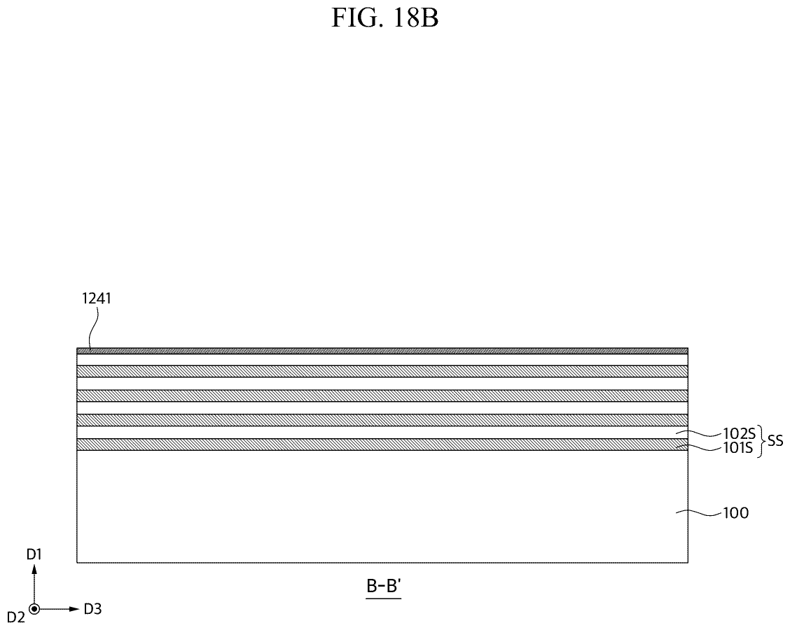

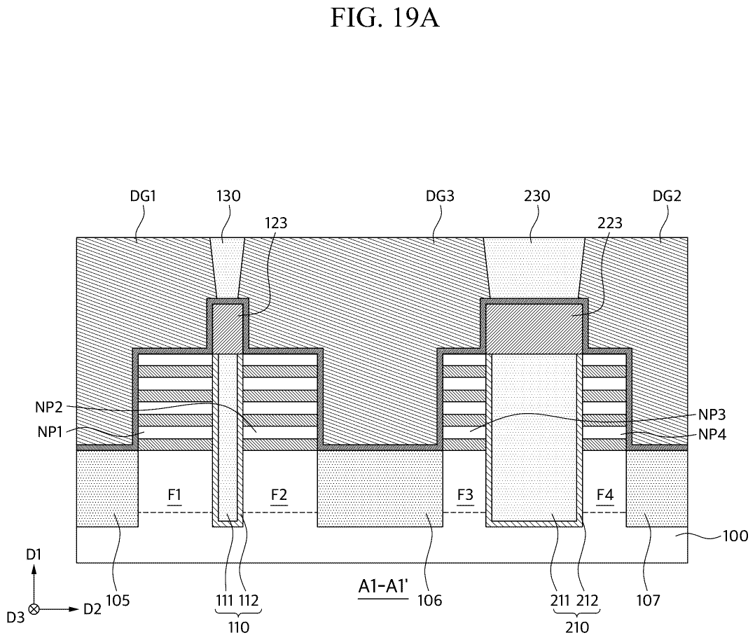

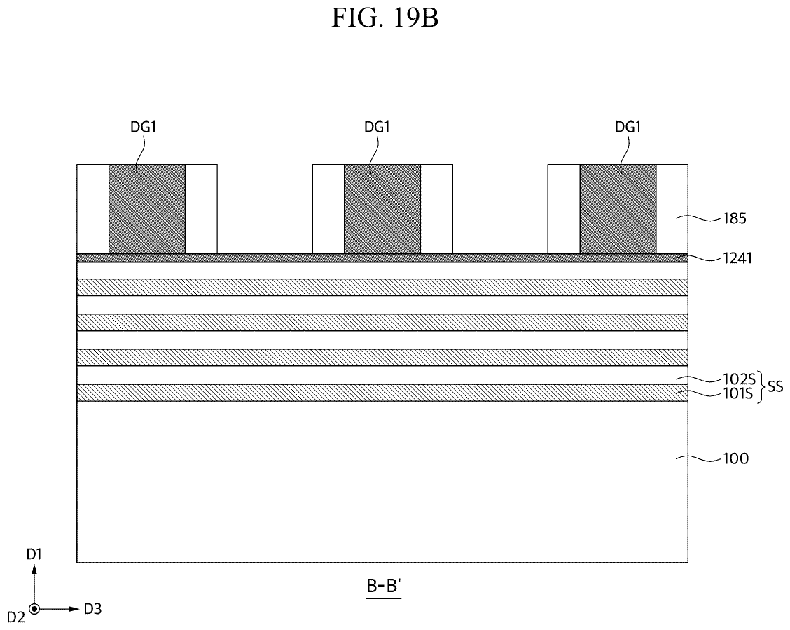

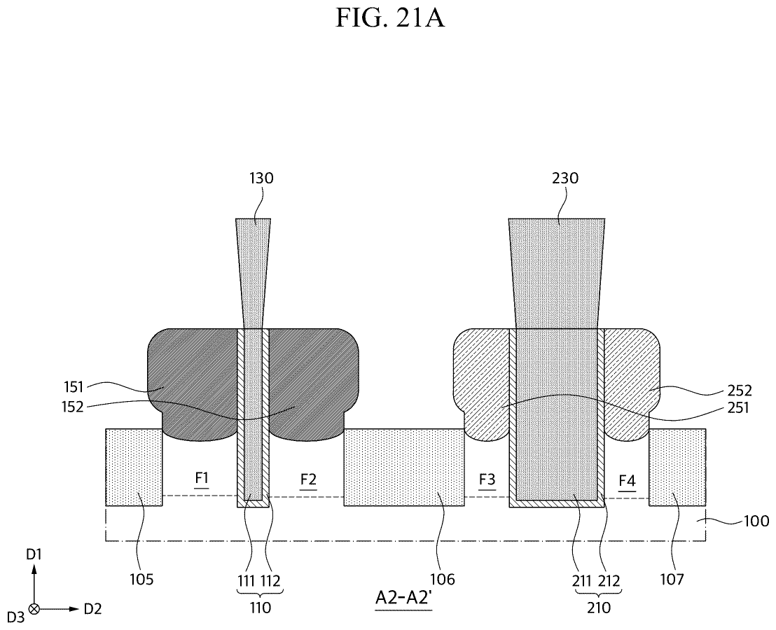

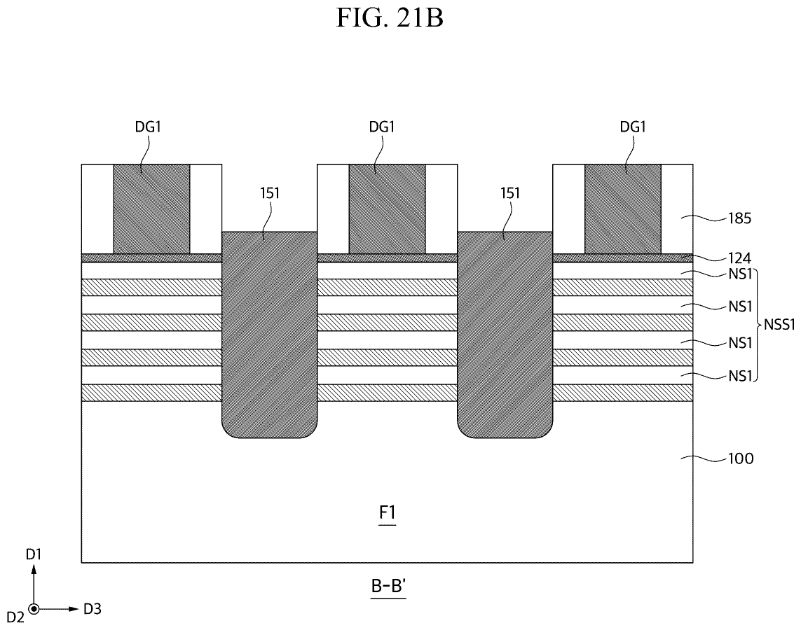

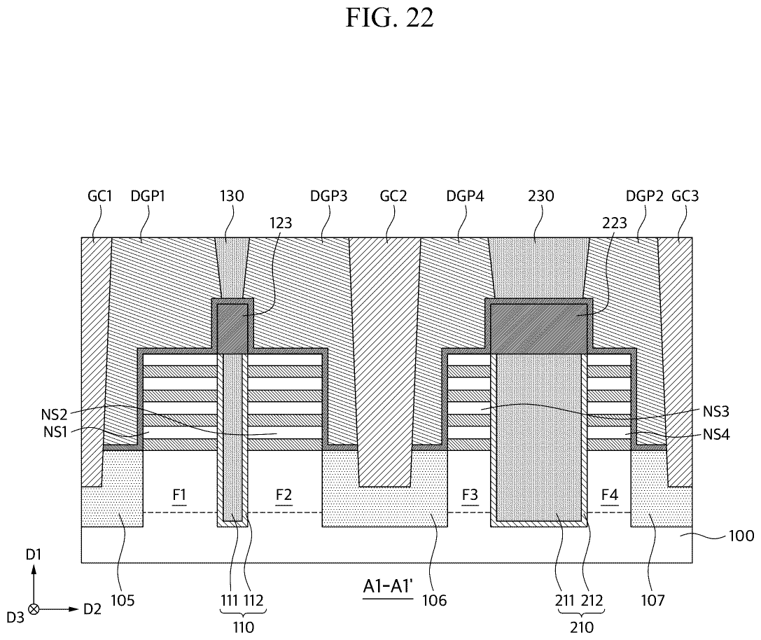

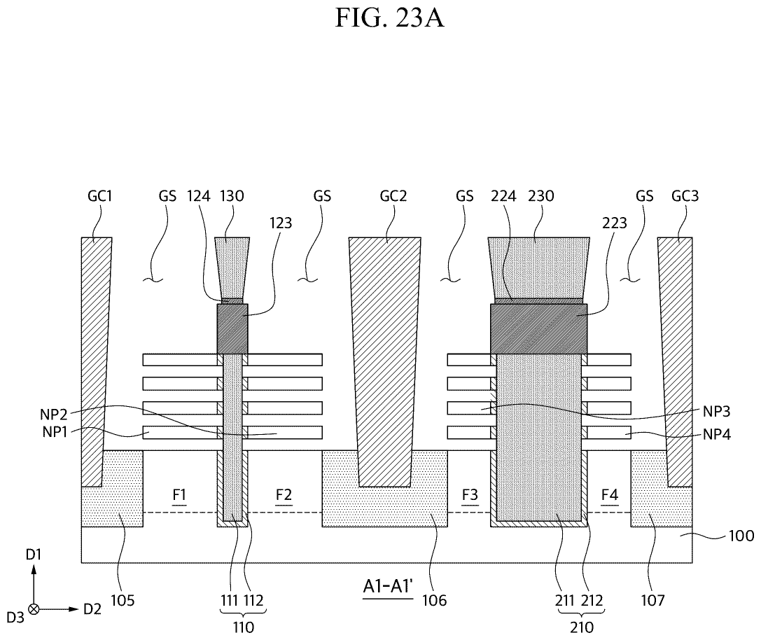

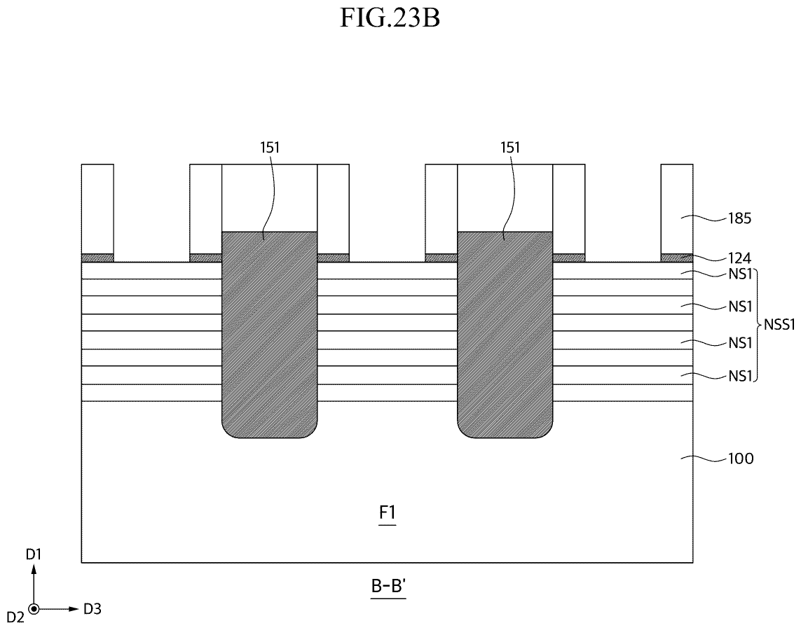

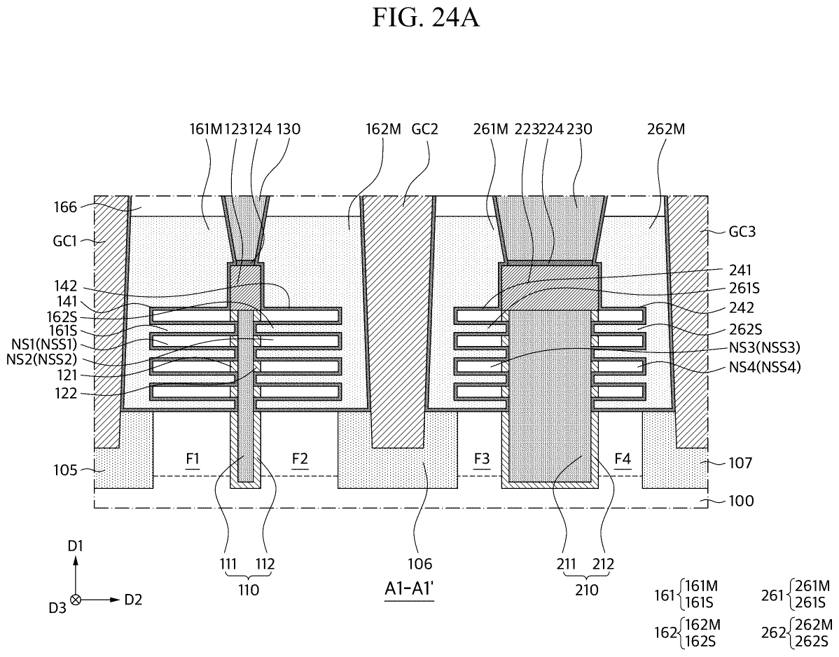

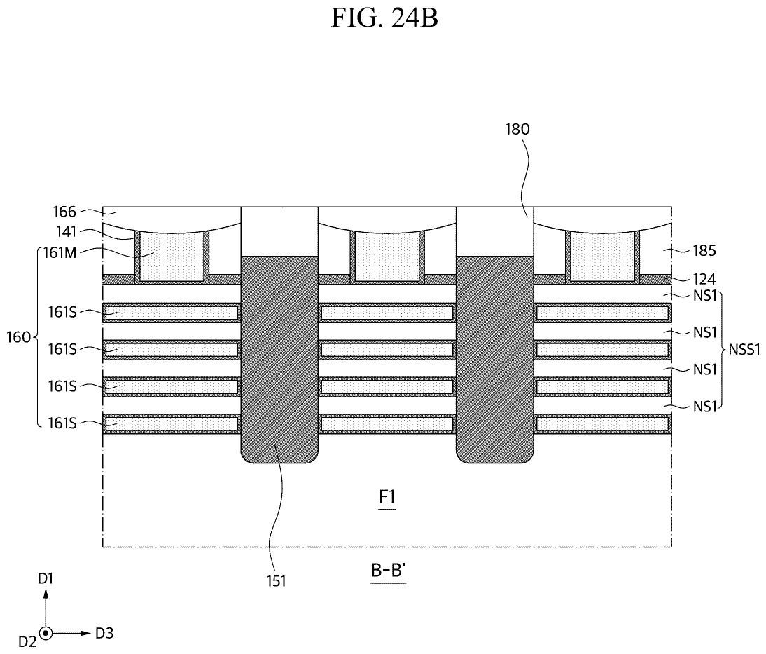

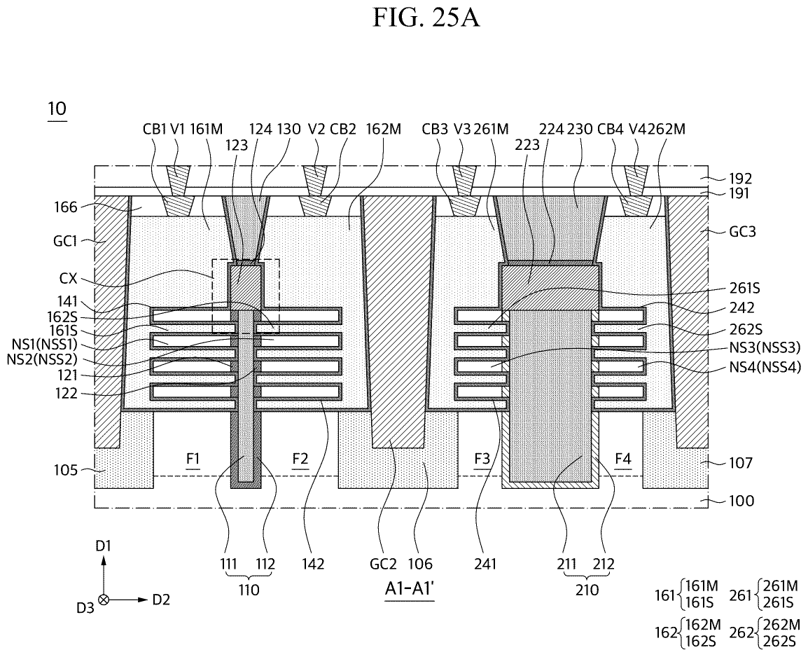

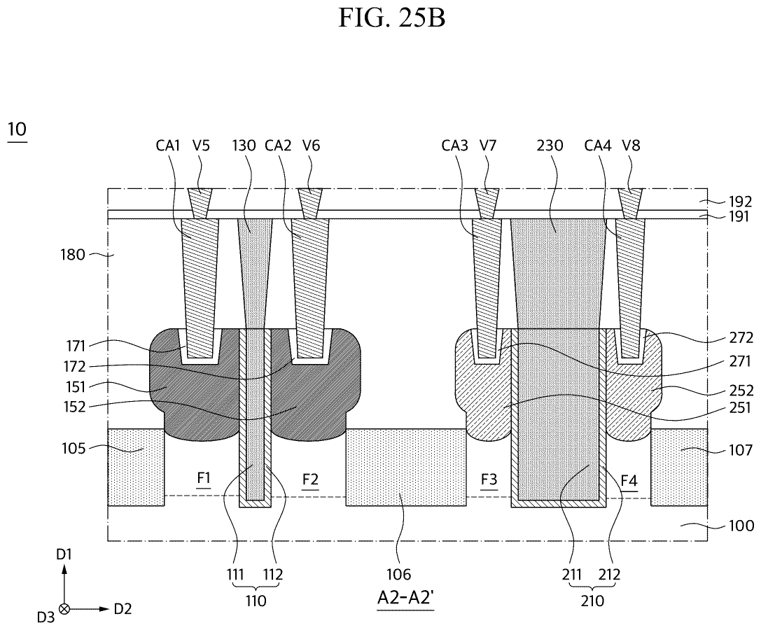

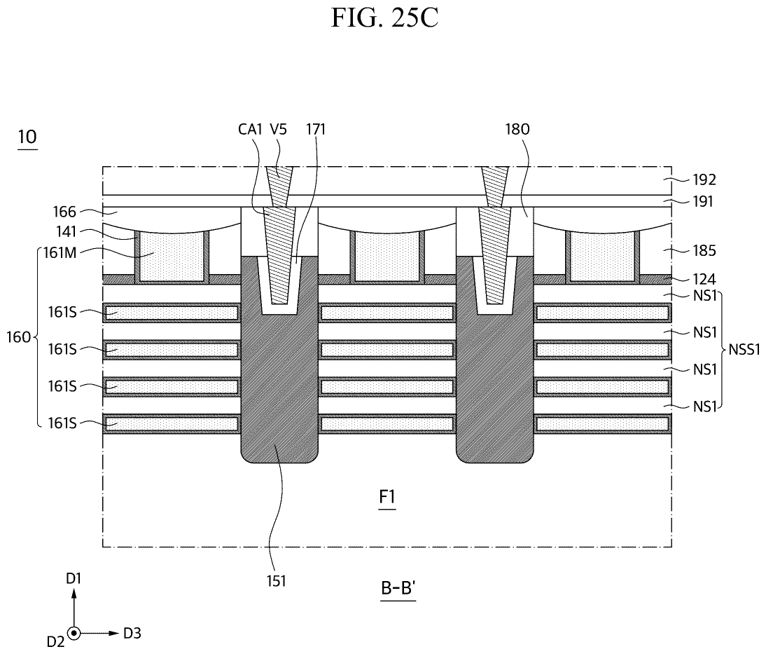

FIG. 10A to FIG. 25C are cross-sectional views illustrating a manufacturing method of the integrated circuit device 10 according to some example embodiments of the technical idea of the present disclosure according to a process sequence. FIG. 10A, FIG. 11, FIG. 12A, FIG. 13, FIG. 14A, FIG. 15, FIG. 16, FIG. 17, FIG. 18A, FIG. 19A, FIG. 22, FIG. 23A, FIG. 24A, and FIG. 25A are cross-sectional views illustrating cross-sectional structures according to the process sequence of a portion corresponding to the cross-section taken along line A1-A1′ of FIG. 1. FIG. 10B, FIG. 12B, FIG. 14B, FIG. 18B, FIG. 19B, FIG. 21B, FIG. 23B, FIG. 24B, and FIG. 25C are cross-sectional views illustrating cross-sectional structures according to the process sequence of a portion corresponding to the B-B′ cross-section of FIG. 1. FIG. 20, FIG. 21A, and FIG. 25B are cross-sectional views illustrating cross-sectional structures according to the process sequence of a portion corresponding to the cross-section taken along line A2-A2′ of FIG. 1.

Referring to FIG. 10A and FIG. 10B, a stacked structure SS may be formed in which a sacrificial film 101S and a semiconductor layer 102S are alternately laminated on the substrate 100. For example, the sacrificial film 101S may be formed at the bottom of the stacked structure SS, and the semiconductor layer 102S may be formed on the top of the stacked structure SS. However, the technical idea of the present disclosure is not limited thereto. In some other example embodiments, the sacrificial film 101S may also be formed on the top of the stacked structure SS. The sacrificial film 101S and the semiconductor layer 102S may be composed of different semiconductor materials. The plurality of semiconductor layers 102S may be composed of a single material. In some example embodiments, the plurality of semiconductor layers 102S may be composed of the same material as the constituent material of the substrate 100. The sacrificial film 101S may include, for example, silicon germanium (SiGe), and the semiconductor layer 102S may include, for example, silicon (Si), but the present disclosure is not limited to the example embodiments.

According to some example embodiments, the plurality of sacrificial films 101S may all be formed with the same thickness, but the technical idea of the present disclosure is not limited thereto. In some example embodiments, among the plurality of sacrificial films 101S, the thickness of the sacrificial film 101S closest to the substrate 100 may be greater than the thicknesses of the other sacrificial films 101S.

As illustrated in FIG. 10A, a capping layer 103S and a mask pattern MP may be formed on the stacked structure SS. The capping layer 103S may extend along the upper surface of the uppermost semiconductor layer 102S. The mask pattern MP may be composed of a plurality of line patterns extending parallel to each other in one direction (for example, the third direction D3).

According to some example embodiments, the capping layer 103S may include, for example, one of silicon nitride (SiN), silicon oxynitride (SiON), silicon oxide (SiO2), silicon oxycarbonitride (SiOCN) and/or a combination thereof. However, the technical idea of the present disclosure is not limited thereto.

According to some example embodiments, the mask pattern MP may be made of silicon nitride, polysilicon, spin-on hardmask (SOH) material, and/or a combination thereof, but the mask pattern MP is not limited thereto. In some example embodiments, the SOH material may be composed of a hydrocarbon compound having a relatively high carbon content of about 85 wt % to about 99 wt % based on the total weight of the SOH material, or its derivatives.

Referring to FIG. 11, using the mask pattern MP as an etching mask, the capping layer 103S, the stacked structure SS, and a portion of the substrate 100 may be etched to form a plurality of trenches (a first trench T1, a second trench T2 and a third trench T3). As a result, the plurality of active areas (the first active area F1 to the fourth active area F4) each extending in the third direction D3 may be formed on the substrate 100. The first active area F1 to the fourth active area F4 may be separated from each other in the second direction D2. The first active area F1 to the fourth active area F4 may be protruded in the first direction D1 from the upper surface of the substrate 100.

A plurality of semiconductor layers (see the semiconductor layer 102S of FIG. 10A) may be etched to extend in the third direction D3, and the plurality of nano patterns (the first nano pattern NP1, the second nano pattern NP2, the third nano pattern NP3 and the fourth nano pattern NP4) spaced in the second direction D2 may be formed. Provided may be the trench T1 that forms the boundary between a first nano pattern NP1 and a second nano pattern NP2, the second trench T2 that forms the boundary between a third nano pattern NP3 and a fourth nano pattern NP4, and the third trench T3 that forms a boundary between the second nano sheet NS2 and the third nano sheet NS3.

Referring to FIG. 12A and FIG. 12B, subsequently, the plurality of active areas (the first active area F1 to the fourth active area F4), the plurality of nano patterns (the first nano pattern NP1 to the fourth nano pattern NP4), the plurality of sacrificial films 101S, and an insulating material layer 1121 covering the side wall of the capping layer 103S may be formed on the substrate 100. The insulating material layer 1121 may also be formed on the upper surface of the nano pattern formed at the top (the first nano pattern NP1 to the fourth nano pattern NP4) and the upper surface of the capping layer 103S. The insulating material layer 1121 may be formed conformally. The insulating material layer 1121 may include, for example, silicon oxide (SiO2) or silicon nitride (SiN). According to some example embodiments, the insulating material layer 1121 may be formed through a process such as chemical vapor deposition (CVD), physical vapor deposition (PVD), or atomic layer deposition (ALD). However, the process by which the insulating material layer 1121 is deposited is not limited to the processes described above.

Referring to FIG. 13, the first filling film 111 may then be formed within the first trench T1, and the second filling film 211 may be formed within the second trench T2. The first filling film 111 and the second filling film 211 may be deposited on the insulating material layer 1121 within the first trench T1 and the second trench T2.

Referring to FIG. 14A and FIG. 14B, a portion of the insulating material layer 1121 (see FIG. 13) may be removed through an etch back process in the resultant of FIG. 13. The etch back process may be a process using a gas containing oxygen, nitrogen, a gas containing fluorine (for example, CF₄, SF₆, CH₂F₂, CHF₃, and/or C₂F₆), a gas containing chlorine (for example, Cl₂, CHCl₃, CCl₄, and /r BCl₃), a gas containing bromine (for example, HBr and/or CHBr3), or a gas containing iodine.

According to some example embodiments, when a portion of the insulating material layer 1121 (see FIG. 13) is removed through the above etch back process, the first insulating liner 112 and the second insulating liner 212 may be formed. When the first insulating liner 112 and the second insulating liner 212 are formed, the first insulating pillar 110 including the first insulating liner 112 and the first filling film 111 and the second insulating pillar 210 including the second insulating liner 212 and the second filling film 211 are completed. The upper surface of the first insulating liner 112 formed through the above etch back process may be positioned on the same plane as the upper surface of the uppermost first nano sheet NS1 or the uppermost second nano sheet NS2. The upper surface of the second insulating liner 212 formed through the etch back process may be positioned on the same plane as the upper surface of the uppermost third nano sheet NS3 or the uppermost fourth nano sheet NS4.

According to some example embodiments, the insulating material layer 1121 (see FIG. 13) exposed to the outside, not enclosed within first trench T1 and second trench T2, or a portion of the insulating material layer 1121 (see FIG. 13) located on the upper surface of the uppermost end nano pattern, may be removed through the etch back process.

Referring to FIG. 15, a capping material layer 1231 may be deposited on the substrate 100. The capping material layer 1231 may cover a side wall of the plurality of active areas (the first active area F1 to the fourth active area F4), a side wall of the plurality of nano patterns (the first nano pattern NP1 to the fourth nano pattern NP4), a side wall of the plurality of sacrificial films 101S, and a side wall of a plurality of capping layers 103S on the substrate 100. In addition thereto, the capping material layer 1231 may cover the upper surface of the capping layer 103S, the upper surface of the first insulating pillar 110, and the upper surface of the second insulating pillar 210. The capping material layer 1231 may include one of silicon nitride (SiN), silicon oxynitride (SiON), silicon oxide (SiO2), silicon oxycarbonitride (SiOCN), and/or a combination thereof. However, the technical idea of the present disclosure is not limited thereto. The capping material layer 1231 may include a material having an etching selectivity for the plurality of filling films (the first filling film 111 and the second filling film 211) and the plurality of insulating liners (the first insulating liner 112 and the second insulating liner 212).

Referring to FIG. 16, a portion of the capping material layer 1231 (see FIG. 15) may then be removed through the etch back process. The etch back process to remove a portion of the capping material layer 1231 (see FIG. 15) may be similar to the etch back process described with reference to FIG. 14A and FIG. 14B.

According to some example embodiments, when a portion of the capping material layer 1231 (see FIG. 15) is removed through the above etch back process, the first insulating cap 123 and the second insulating cap 223 may be formed. The upper surface of the first insulating cap 123 and the upper surface of the second insulating cap 223 that are formed in the etch back process may be positioned on the same plane as the upper surface of the capping layer 103S.

Referring to FIG. 17, the plurality of field insulating films (the first field insulating film 105 to the third field insulating film 107) are formed on the substrate 100. The field insulating film (the first field insulating film 105 to the third field insulating film 107) may be formed in the space between the plurality of active areas (the first active area F1 to the fourth active area F4). For example, the first field insulating film 105 may be formed to cover the side wall of the first active area F1, the second field insulating film 106 may be formed to cover the side wall of the second active area F2 and the side wall of the third active area F3, and the third field insulating film 107 may be formed to cover the side wall of the fourth active area F4. According to some example embodiments, the upper surfaces of plurality of field insulating films (the first field insulating film 105 to the third field insulating film 107) may be formed to be coplanar with the upper surfaces of the plurality of active areas (the first active area F1 to the fourth active area F4).

In the present disclosure, the field insulating films (the first field insulating film 105 to the third field insulating film 107) are depicted as if they were a single material layer. However, in some example embodiments, the field insulating film (the first field insulating film 105 to the third field insulating film 107) may include an insulating liner (not illustrated) that conformally covers the substrate 100 and the plurality of active areas (the first active area F1 to the fourth active area F4) and a gap-fill insulating film that fills a space between the plurality of active areas (the first active area F1 to the fourth active area F4) on the insulating liner.

According to some example embodiments, the plurality of field insulating films (the first field insulating film 105 to the third field insulating film 107) may include an oxide film. In some example embodiments, the plurality of field insulating films (the first field insulating film 105 to the third field insulating film 107) may be formed by an oxide film formed by a deposition process or a coating process. In some example embodiments, the plurality of field insulating films (the first field insulating film 105 to the third field insulating film 107) may be formed by an oxide film formed by a flowable chemical vapor deposition (FCVD) process or a spin coating process. However, the process by which the field insulating film (the first field insulating film 105 to the third field insulating film 107) is formed is not necessarily limited to the process described above.

Referring to FIG. 18A and FIG. 18B, subsequently, an upper insulating material 1241 may be formed that covers side walls of the plurality of nano patterns (the first nano pattern NP1 to the fourth nano pattern NP4) on the plurality of field insulating films (the first field insulating film 105 to the third field insulating film 107), the plurality of sacrificial films 101S, the first insulating cap 123, and the second insulating cap 223. The upper insulating material 1241 may also be formed on the upper surface of the first insulating cap 123, the upper surface of the second insulating cap 223, and the upper surfaces of a plurality of uppermost nano patterns (the first nano pattern NP1 to the fourth nano pattern NP4). For example, the upper insulating material 1241 may be conformally formed. The upper insulating material 1241 may include, for example, silicon oxide (SiO2) or silicon nitride (SiN). According to some example embodiments, the upper insulating material 1241 may be formed through a process such as CVD, PVD and ALD. However, the process by which the upper insulating material 1241 is deposited is not limited to the processes listed above.

Referring to FIG. 19A and FIG. 19B, the first upper insulting pillar 130 may be formed to overlap the first insulating pillar 110 in the first direction D1, and the second super insulting pillar 230 may be formed to overlap the second insulating pillar 210 in the first direction D1. The first upper insulting pillar 130 and the second upper insulting pillar 230 may be formed through a lithography process. However, the process by which the first upper insulting pillar 130 and the second upper insulting pillar 230 are formed is not necessarily limited to the above.

According to some example embodiments, the first upper insulting pillar 130 may be formed on the upper insulating material 1241 so as to overlap the first insulating pillar 110, or may be formed on the first filling film 111 to overlap the first insulating pillar 110. The second upper insulting pillar 230 may be formed on the upper insulating material 1241 to overlap the second insulating pillar 210, or may be formed on the second filling film 211 so as to overlap the second insulating pillar 210.

After then, a first dummy gate DG1 to a third dummy gate DG3 may be formed on the upper insulating material 1241. The third dummy gate DG3 may be separated from the first dummy gate DG1 in the second direction D2. Further, a second dummy gate DG2 may be separated from the third dummy gate DG3 in the second direction D2. In other words, the third dummy gate DG3 may be formed between the first dummy gate DG1 and the second dummy gate DG2.

According to some example embodiments, the first upper insulting pillar 130 may act as a separating film between the first dummy gate DG1 and the third dummy gate DG3, and the second upper insulting pillar 230 may act as a separating film between the second dummy gate DG2 and the third dummy gate DG3.

However, in some example embodiments, after forming the first dummy gate DG1 to the third dummy gate DG3, the first upper insulting pillar and the second upper insulting pillar 230 may also be formed.

Next, the gate spacer 185 may be formed extending in the second direction D2 along both side walls of the first dummy gate DG1 to the third dummy gate DG3, respectively.

Referring to FIG. 20, a portion of the plurality of each of the nano patterns (the first nano pattern NP1 to the fourth nano pattern NP4), a portion of each of the plurality of insulating caps (the first insulating cap 123 and the second insulating cap 223), a portion of each of the plurality of sacrificial films 101S, and a portion of the upper insulating material 1241 may be removed in the etching process. Here, the etching process may be performed in order for a pattern to be formed in the second direction D2. Even though not depicted in detail in the drawing, in order to perform the etching process, a mask extending in the second direction D2 may be formed on the upper insulating material 1241. The material covered by the above mask is not removed by the above etching process.

According to some example embodiments, completely removed in the etching process may be the portion of the plurality of each of the nano patterns (the first nano pattern NP1 to the fourth nano pattern NP4), the portion of each of the plurality of insulating caps (the first insulating cap 123 and the second insulating cap 223), the portion of each of the plurality of sacrificial films 101S, and the portion of the upper insulating material 1241, which are not covered by the mask. Further, in the etching process, a portion of the first active area F1 to the fourth active area F4 may be removed to form the first recess R1 to the fourth recess R4.

According to some example embodiments, the first recess R1 may be defined as the area where a portion of the first active area F1 is etched, and the second recess R2 may be defined as an area where a portion of the second active area F2 is etched. The third recess R3 may be defined as an area where a portion of the third active area F3 is etched, and the fourth recess R4 may be defined as an area where a portion of the fourth active area F4 is etched.

According to an example embodiment, with regard to the etching process, dry etching, wet etching, or a combination of dry and wet etching processes may be used.

In case the plurality of insulating caps (the first insulating cap 123 and the second insulating cap 223) and the upper insulating material 1241 remain unetched and protected by a mask, the first upper insulting pillar 130 and the second upper insulting pillar 230 may be formed on the upper insulating material 1241. In a case that when the plurality of insulating caps (the first insulating cap 123 and the second insulating cap 223) and the upper insulating material 1241 are removed, the upper surfaces of the first filling film 111 and the second filling film 211 are exposed, the first upper insulting pillar 130 and the second upper insulting pillar 230 may be formed on the upper surface of the first filling film 111 and the second filling film 211.

Referring to FIG. 21A and FIG. 21B, the first source/drain area 151 may then be formed between a pair of first nano sheets NS1 arranged in the first recess R1 of the first active area F1 in the third direction D3. Further, the second source/drain area 152 may be formed between a pair of second nano sheets NS2 arranged in the second recess R2 of the second active area F2 in the third direction D3. The third source/drain area 251 may be formed between a pair of third nano sheets NS3 arranged in the third direction D3 in the third recess R3 of the third active area F3. The fourth source/drain area 252 may be formed between a pair of fourth nano sheets NS4 arranged in the third direction D3 in the fourth recess R4 of the fourth active area F4.

For example, the upper surface of each of the first source/drain area 151 to the fourth source/drain area 252 may be formed higher than the uppermost surface of each of the first upper filling films 124. However, the technical idea of the present disclosure is not limited thereto. The first source/drain area 151 to the fourth source/drain area 252 may be formed by epitaxial growth of a semiconductor material on the first recess R1 to the fourth recess R4.

As illustrated in FIG. 21B, using the first dummy gate DG1 to the third dummy gate DG3 and the gate spacer 185 as a mask pattern, the upper insulating material 1241, the plurality of sacrificial films 101S, and the plurality of nano patterns (the first nano pattern NP1 to the fourth nano pattern NP4) may be etched. For example, while the sacrificial film 101S and the plurality of nano patterns (the first nano pattern NP1 to the fourth nano pattern NP4) are etched, a portion of each of the plurality of active areas (the first active area F1 to the fourth active area F4) may also be etched.

According to some example embodiments, the upper insulating material 1241 (see FIG. 20a and FIG. 20b) remaining unetched at the bottom of the plurality of dummy gates (the first dummy gate DG1 to the third dummy gate DG3) may be defined as the first upper filling film 124.

Further, a plurality of first nano patterns NP1 that remain unetched at the bottom of the first dummy gate DG1 may be defined as the plurality of first nano sheets NS1. The plurality of second nano patterns NP2 (see FIG. 19A) and a plurality of third nano patterns NP3 (see FIG. 19A) that remain unetched at the bottom of the third dummy gate DG3 (see FIG. 19A) may be defined as the plurality of second nano sheets NS2 (see FIG. 22) and the plurality of third nano sheets NS3 (see FIG. 22). The plurality of fourth nano patterns NP4 (see FIG. 19A) that remain unetched at the bottom of the second dummy gate DG2 (see FIG. 19A) may be defined as the plurality of fourth nano sheets NS4 (see FIG. 22).

Referring to FIG. 22, the first dummy gate DG1 to the third dummy gate DG3 (see FIG. 19A) may be formed by penetrating first dummy gate DG1 to the third dummy gate DG3 with a respective first gate cut GC1 to third gate cut GC3 in the first direction D1, thereby separating the first dummy gate DG1 to the third dummy gate DG3 (see FIG. 19A). For example, the plurality of gate cuts (the first gate cut GC1 to the third gate cut GC3) may be formed to extend through the first dummy gate DG1 to the third dummy gate DG3 (see FIG. 19A) toward the first field insulating film 105 to the third field insulating film 107. A dummy gate pattern located between the first gate cut GC1 and one side of the first insulating pillar 110 may be defined as a first dummy gate pattern DGP1. A dummy gate pattern located between the second gate cut GC2 and the other side that is opposite to the one side of the first insulating pillar 110 may be defined as a third dummy gate pattern DGP3. A gate pattern located between the second gate cut GC2 and one side of the second insulating pillar 210 may be defined as a fourth dummy gate pattern DGP4. A dummy gate pattern located between the third gate cut GC3 and the other side that is opposite to the one side of the second insulating pillar 210 may be defined as a second dummy gate pattern DGP2.

Referring to FIG. 23A and FIG. 23B, from the result of FIG. 22, a gate space GS may be prepared by removing each of the first dummy gate pattern DGP1 to the fourth dummy gate pattern DGP4 and the first upper filling film 124, and the first nano sheet stack NSS1 to the fourth nano sheet stack NSS4 may be exposed through the gate space GS. After then, by removing the plurality of sacrificial films 101S remaining on the first active area F1 to the fourth active area F4 through the gate space GS, the gate space GS may be extended to the space between each of the first nano sheet to fourth nano sheet NS4, and to the space between the first nano sheet NS1 to the fourth nano sheet NS4 and the first active area F1 to the fourth active area F4. In some example embodiments, in order to selectively remove the plurality of sacrificial films 101S, the difference in etching selectivity between the first nano sheet NS1 to the fourth nano sheet NS4 and the plurality of sacrificial films 101S may be utilized.

According to some example embodiments, liquid or gaseous etchants may be used to selectively remove the plurality of sacrificial films 101S. In some example embodiments, in order to selectively remove the plurality of sacrificial films 101S, an etchant based on CH3COOH, for example, an etchant including a mixture of CH3COOH, HNO3, and HF, or an etchant including a mixture of CH3COOH, H2O2, and HF may be used. However, the present disclosure is not limited thereto.

Referring to FIG. 24A and FIG. 24B, in the results of FIG. 23A and FIG. 23B, the plurality of gate dielectric films (the first gate dielectric film 141, the second gate dielectric film 142, the third gate dielectric film 241 and the fourth gate dielectric film 242) may be formed covering the exposed surfaces of the first nano sheet NS1 to the fourth nano sheet NS4, the first gate cut GC1 to the third gate cut GC3, and the first active area F1 to the fourth active area F4, respectively. Among the plurality of gate dielectric films (the first gate dielectric film 141, the second gate dielectric film 142, the third gate dielectric film 241 and the fourth gate dielectric film 242), the gate dielectric film covering the exposed surface of the first active area F1 and the first nano sheet NS1 may be defined as the first gate dielectric film 141. Among the plurality of gate dielectric films (the first gate dielectric film 141, the second gate dielectric film 142, the third gate dielectric film 241 and the fourth gate dielectric film 242), the gate dielectric film covering the exposed surfaces of the second active area F2 and the second nano sheet NS2 may be defined as the second gate dielectric film 142. Among the plurality of gate dielectric films (the first gate dielectric film 141, the second gate dielectric film 142, the third gate dielectric film 241 and the fourth gate dielectric film 242), the gate dielectric film covering the exposed surfaces of the third active area F3 and the third nano sheet NS3 may be defined as the third gate dielectric film 241. Among the plurality of gate dielectric films (the first gate dielectric film 141, the second gate dielectric film 142, the third gate dielectric film 241 and the fourth gate dielectric film 242), the gate dielectric film covering the exposed surface of the fourth active area F4 and the fourth nano sheet NS4 may be defined as the fourth gate dielectric film 242. The ALD process may be used to form the first gate dielectric film to the fourth gate dielectric film 242.

Subsequently, while filling the gate space GS on the first gate dielectric film to the fourth gate dielectric film 242, the plurality of gate lines (the first gate line 161, the second gate line 162, the third gate line 261, and the fourth gate line 262) may be formed. The first gate line 161 may cover the first gate dielectric film 141, the second gate line 162 may cover the second gate dielectric film 142, the third gate line 261 may cover the third gate dielectric film 241, and the fourth gate line 262 may cover the fourth gate dielectric film 242.

According to some example embodiments, each of the first gate line to the fourth gate line (the first gate line 161, the second gate line 162, the third gate line 261, and the fourth gate line 262) may include a metal-containing layer for work function control and a gap-filling metal-containing layer filling an upper space of the metal-containing layer for work function control. In some example embodiments, the first gate line to the fourth gate line (the first gate line 161, the second gate line 162, the third gate line 261, and the fourth gate line 262) may have a structure in which a metal nitride layer, a metal layer, a conductive capping layer, and a gap-fill metal film are sequentially laminated. The metal nitride layer and metal layer may be formed by an ALD, MOALD (metal organic ALD), or MOCVD (metal organic CVD) process, respectively. The conductive capping layer may act as a protective film to prevent, or reduce in likelihood, the surface of the metal layer from being oxidized. Further, the conductive capping layer may act as a wetting layer to facilitate deposition when another conductive layer is deposited on the metal layer. The gap-fill metal film may extend over the conductive capping layer. The gap-fill metal film may be formed by the ALD, CVD, or PVD process. In some example embodiments, the first gate line to the fourth gate line (the first gate line 161, the second gate line 162, the third gate line 261, and the fourth gate line 262) may include a laminated structure of TiAlC/TiN/W or a laminated structure of TiN/TaN/TiAlC/TiN/W or a laminated structure of TiN/TaN/TiN/TiAlC/TiN/W. In the laminated structures, the TiAlC layer or the TiN layer may serve as a metal-containing layer for work function control.

According to some example embodiments, the first gate line 161 may include the first main gate part 161M covering an upper surface of the first nano sheet stack NSS1 including the plurality of first nano sheets NS1, and a plurality of first sub gate parts 161S connected to the first main gate part 161M and formed in the space between each of the plurality of first nano sheets NS1 and the first active area F1.

According to some example embodiments, the second gate line 162 may include the second main gate part 162M covering an upper surface of the second nano sheet stack NSS2 including the plurality of second nano sheets NS2, and the plurality of second sub gate parts 162S connected to the second main gate part 162M and formed in the space between each of the second nano sheets NS2 and the second active area F2.

According to some example embodiments, the third gate line 261 may include the third main gate part 261M covering an upper surface of the third nano sheet stack NSS3 including the plurality of third nano sheets NS3, and the plurality of third sub gate parts 261S connected to the third main gate part 261M and formed in the space between each of the plurality of third nano sheets NS3 and the third active area F3.

According to some example embodiments, the fourth gate line 262 may include the fourth main gate part 262M covering an upper surface of the fourth nano sheet stack NSS4 including the plurality of fourth nano sheets NS4, and the plurality of fourth sub gate parts 262S connected to the fourth main gate part 262M and formed in the space between each of the fourth nano sheets NS4 and the fourth active area F4.

Subsequently, the capping pattern 166 may be formed that covers the plurality of gate lines (the first gate line 161, the second gate line 162, the third gate line 261, and the fourth gate line 262).

Referring to FIG. 25A, FIG. 25B, and FIG. 25C, the first gate contact CB1 to the fourth gate contact CB4 may be formed by penetrating the capping pattern 166 in the first direction D1 and connecting to one of the first gate line 161 to the fourth gate line 262.

Further, the first interlayer insulating film 180 covering the first source/drain area 151 to the fourth source/drain area 252 may be formed on the first field insulating film 105 to the third field insulating film 107. The first interlayer insulating film 180 may contain silicon oxide. After then, the first source/drain contact CA1 to the fourth source/drain contact CA4 may be formed by penetrating the first interlayer insulating film 180 in the first direction D1 and connecting to one of the first source/drain area 151 to the fourth source/drain area 252. The first source/drain contact CA1 may be connected to the first source/drain area 151, the second source/drain contact CA2 may be connected to the second source/drain area 152, the third source/drain contact CA3 may be connected to the third source/drain area 251, and the fourth source/drain contact CA4 may be connected to the fourth source/drain area 252.

According to some example embodiments, the plurality of silicide layers (first silicide layer 171 to the fourth silicide layer 272) may be formed between each of the first source/drain area 151 to the fourth source/drain area 252 and the first source/drain contact CA1 to the fourth source/drain contact CA4. The first silicide layer 171 may be formed between the first source/drain area 151 and the first source/drain contact CA1, the second silicide layer 172 may be formed between the second source/drain area 152 and the second source/drain contact CA2, a third silicide layer 271 may be formed between the third source/drain area 251 and the third source/drain contact CA3, and the fourth silicide layer 272 may be formed between the fourth source/drain area 252 and the fourth source/drain contact CA4.

Subsequently, the etching stopping film 191 and the second interlayer insulating film 192 may be formed sequentially on the first gate cut GC1 to the third gate cut GC3, the capping pattern 166, the first source/drain contact CA1 to the fourth source/drain contact CA4, the first gate contact CB1 to the fourth gate contact CB4, the first upper insulting pillar and the second upper insulting pillar 230. After then, the first via V1 to the fourth via V4, which are connected to the first gate contact CB1 to the fourth gate contact CB4 respectively, may be formed by penetrating the second interlayer insulating film 192 and the etching stopping film 191 in the first direction D1. Further, the fifth via V5 to the eighth via V8, which are connected to the first source/drain contact CA1 to the fourth source/drain contact CA4, may be formed by penetrating the second interlayer insulating film 192 and the etching stopping film 191 in the first direction D1. Through the manufacturing process, the integrated circuit device 10 illustrated in FIG. 1 to FIG. 5 may be manufactured.

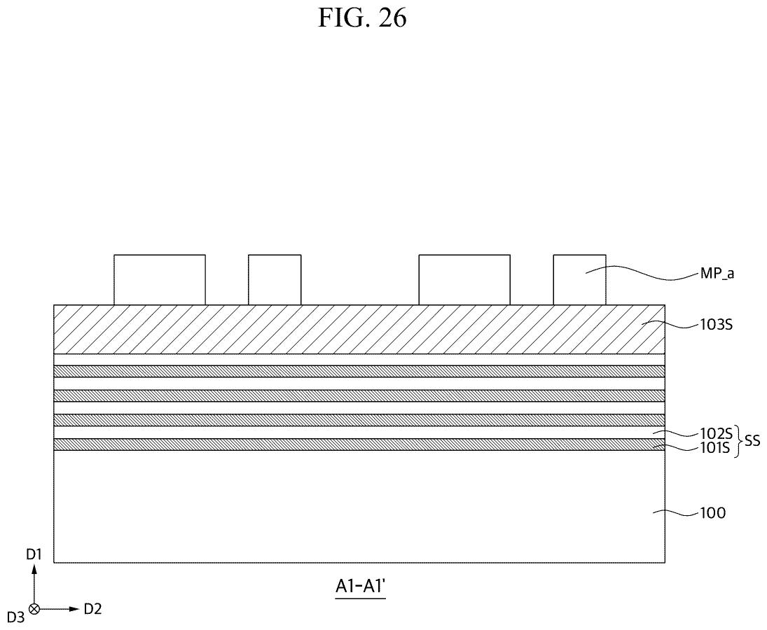

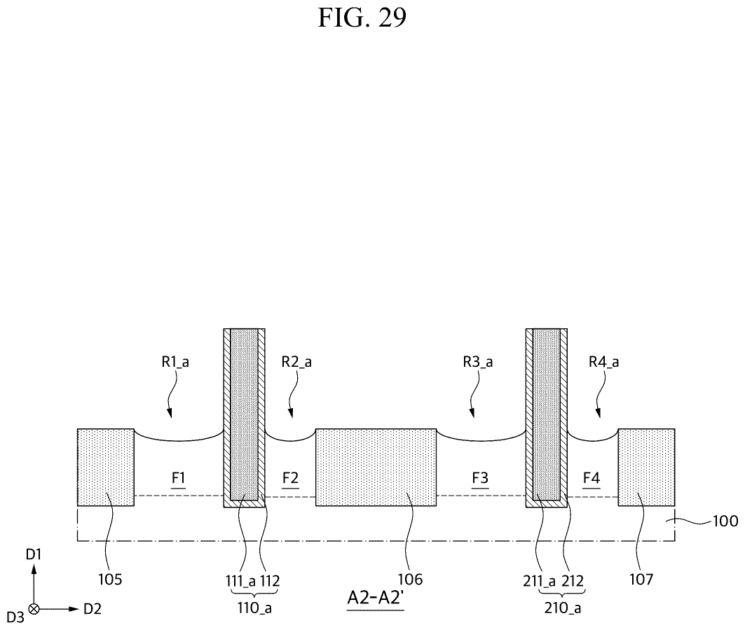

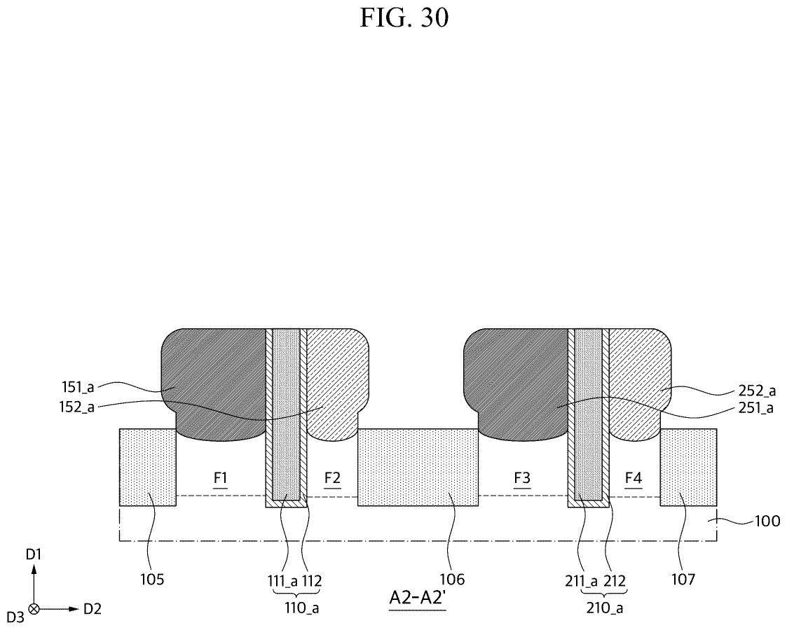

FIG. 26 to FIG. 30 are cross-sectional views illustrating a manufacturing method of the integrated circuit device 20 in the process sequence according to some example embodiments of the technical idea of the present disclosure. FIG. 26 to FIG. 28 are cross-sectional views illustrating cross-sectional structures according to the process sequence of a portion corresponding to the cross-section along line A1_a-A1_a′ of FIG. 7A. FIG. 29 and FIG. 30 are cross-sectional views illustrating cross-sectional structures according to the process sequence of a part corresponding to the cross-section along line A2_a-A2_a′ of FIG. 7B.

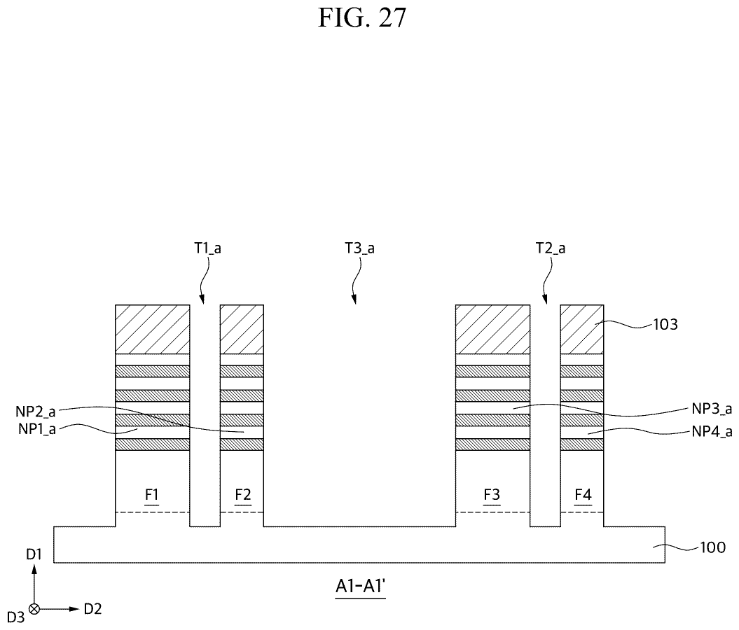

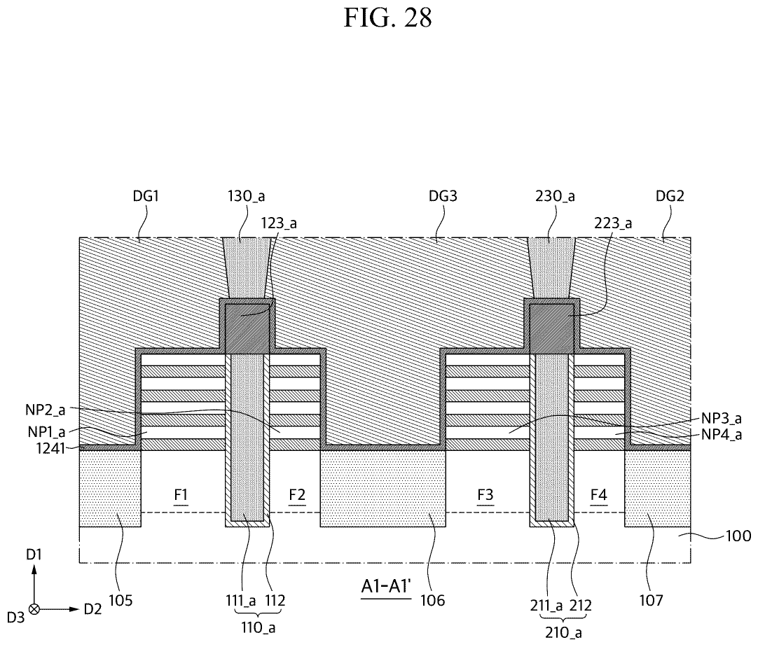

Specifically, FIG. 26 corresponds to FIG. 10A, and FIG. 27 corresponds to FIG. 11, and FIG. 28 corresponds to FIG. 19A. Further, FIG. 29 corresponds to FIG. 20, and FIG. 30 corresponds to FIG. 21A. Below, described are differences from the description of the manufacturing process of the integrated circuit device 10 with reference to FIG. 1 to FIG. 5.

Referring to FIG. 26, the capping layer 103S and a plurality of mask patterns MP_a may be formed on the stacked structure SS including the sacrificial film 101S and the semiconductor layer 102S alternately stacked on the substrate 100. Here, unlike the plurality of mask patterns MP illustrated in FIG. 10A, the widths of the plurality of mask patterns MP_a spaced in the second direction D2 may be different from each other.

Referring to FIG. 27, the plurality of mask patterns MP_a may be used as an etching mask to etch a portion of the stacked structure SS and the substrate 100 to form a plurality of trenches (a first trench T1_a, a second trench T2_a, and a third trench T3_a). Here, unlike the plurality of trenches (the first trench T1, the second trench T2 and the third trench T3) illustrated in FIG. 11, the distance between the third trench T3_a and the first trench T1_a in the second direction D2 may be different from the distance between the third trench T3_a and the second trench T2_a in the second direction D2. Further, unlike the first trench T1 and the second trench T2 illustrated in FIG. 11, the first trench T1_a and the second trench T2_a illustrated in FIG. 27 may have the same width in the second direction D2.

Referring to FIG. 28, the field insulating film (the first field insulating film 105 to the third field insulating film 107) and the first insulating pillar 110_a and the second insulating pillar 210_a are formed within the plurality of trenches (the first trench T1_a, the second trench T2_a, and the third trench T3_a). The first insulating cap 123_a and the second insulating cap 223_a may be provided on the first insulating pillar 110_a and the second insulating pillar 210_a. After then, the upper insulating material 1241 may be deposited to cover side walls of the plurality of sacrificial films 101S and a plurality of nano patterns (a first nano pattern NP1_a to a fourth nano pattern NP4_a) and to cover the side walls of the first insulating cap 123_a and the second insulating cap 223_a. The upper insulating material 1241 may also cover the upper surfaces of the plurality of field insulating films (the first field insulating film 105 to the third field insulating film 107), the upper surfaces of the first insulating cap 123_a and the second insulating cap 223_a, and the upper surfaces of the uppermost nano pattern (the first nano pattern NP1_a to the fourth nano pattern NP4_a). After depositing the upper insulating material 1241, a first upper insulting pillar 130_a overlapping the first insulating pillar 110_a and a second upper insulting pillar 230_a overlapping the second insulating pillar 210_a may be formed on the upper insulating material 1241.

According to some example embodiments, after forming the first upper insulting pillar 130_a and the second upper insulting pillar 230_a, the first dummy gate DG1 to the third dummy gate DG3 may be formed. However, according to some example embodiments, after forming the first dummy gate DG1 to the third dummy gate DG3, the first upper insulting pillar 130_a and the second upper insulting pillar 230_a may also be formed.

According to some example embodiments, the first insulating pillar 110_a and the second insulating pillar 210_a may have the same width in the second direction D2.

According to some example embodiments, the width of the first nano pattern NP1_a in the second direction D2 and the width of a third nano pattern NP3_a in the second direction D2 may be the same, and the width of a second nano pattern NP2_a in the second direction D2 and the width of the fourth nano pattern NP4_a in the second direction D2 may be the same. Here, the width of the first nano pattern NP1_a may be greater than the width of the second nano pattern NP2_a.

According to some example embodiments, the first insulating pillar 110_a may be positioned offset from the center between the adjacent first field insulating film 105 and second field insulating film 106 in the second direction D2. Similarly, the second insulating pillar 210_a may also be positioned offset from the center between the adjacent second field insulating film 106 and third field insulating film 107 in the second direction D2.

Referring to FIG. 29, a portion of each of the plurality of nano patterns (the first nano pattern NP1_a to the fourth nano pattern NP4_a) (see FIG. 28), a portion of each of the plurality of the insulating caps (the first insulating cap 123_a and the second insulating cap 223_a) (see FIG. 28), a portion of each of the plurality of sacrificial films 101S (see FIG. 28), and a portion of the upper insulating material 1241 (see FIG. 28) may be removed in the etching process.

According to some example embodiments, the portion of each of the plurality of nano patterns (the first nano pattern NP1_a to the fourth nano pattern NP4_a) (see FIG. 28), the portion of each of the plurality of the insulating caps (the first insulating cap 123_a and the second insulating cap 223_a) (see FIG. 28), the portion of the plurality of sacrificial films 101S (see FIG. 28), and a portion of the upper insulating material 1241 (see FIG. 28), which are not covered by the mask are completely removed in the etching process. Further, in the etching process, a portion of the first active area F1 to the fourth active area F4 may be removed to form a first recess R1_a to a fourth recess R4_a. Any descriptions that overlap with those already described in detail with reference to FIG. 20 are omitted.

The first recess R1_a illustrated in FIG. 29 may have substantially the same width as a third recess R3_a in the second direction D2, and a second recess R2_a may have substantially the same width as the fourth recess R4_a in the second direction D2.

Referring to FIG. 30, the first source/drain area 151_a may be formed between a pair of nano sheets arranged in the third direction D3 on the first recess R1_a of the first active area F1. Further, the second source/drain area 152_a may be formed between a pair of nano sheets arranged in the third direction D3 on the second recess R2_a of the second active area F2. The third source/drain area 251_a may be formed between a pair of nano sheets arranged in the third direction D3 on the third recess R3_a of the third active area F3. The fourth source/drain area 252_a may be formed between a pair of nano sheets arranged in the third direction D3 on the fourth recess R4_a of the fourth active area F4.

According to some example embodiments, each of the first source/drain area to the fourth source/drain area (the first source/drain area 151_a, the second source/drain area 152_a, the third source/drain area 251_a, and the fourth source/drain area 252_a) may fill the corresponding recess among the first recess R1_a to the fourth recess R4_a. The first source/drain area 151_a illustrated in FIG. 29 may have substantially the same longest width as the third source/drain area 251 in the second direction D2, and the second source/drain area 152_a may have substantially the same longest width as the fourth source/drain area 252_a in the second direction D2. Further, the first source/drain area 151_a and the third source/drain area 251_a may be p-type source/drain areas having holes as carriers, and the second source/drain area 152_a and the fourth source/drain area 252_a may be n-type source/drain areas having electrons as carriers.

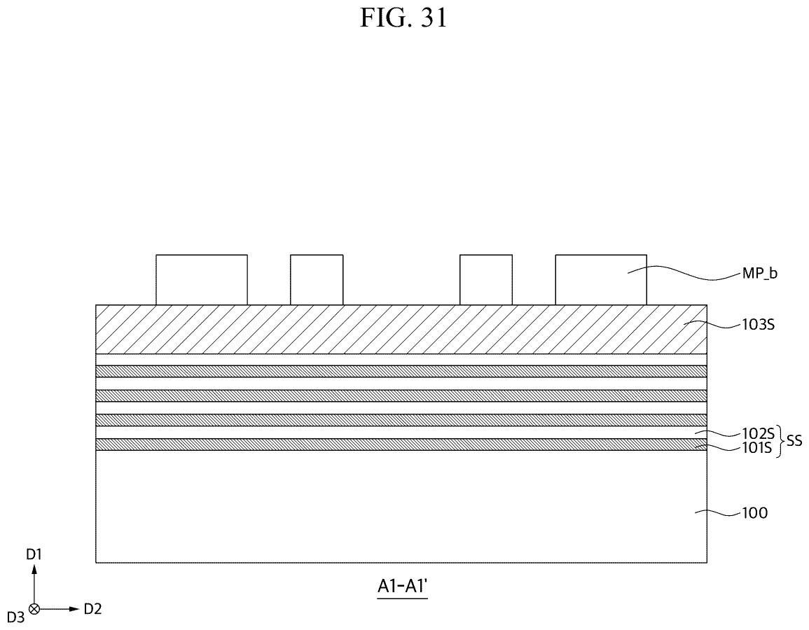

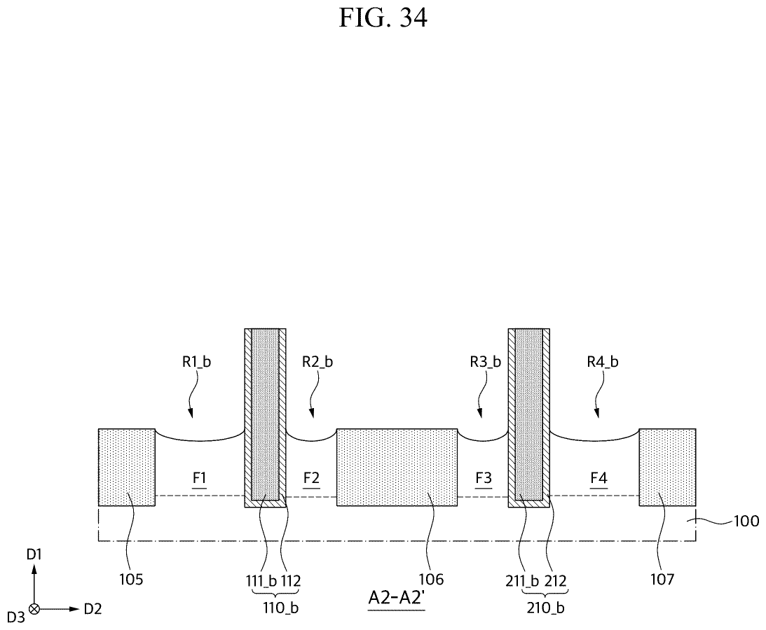

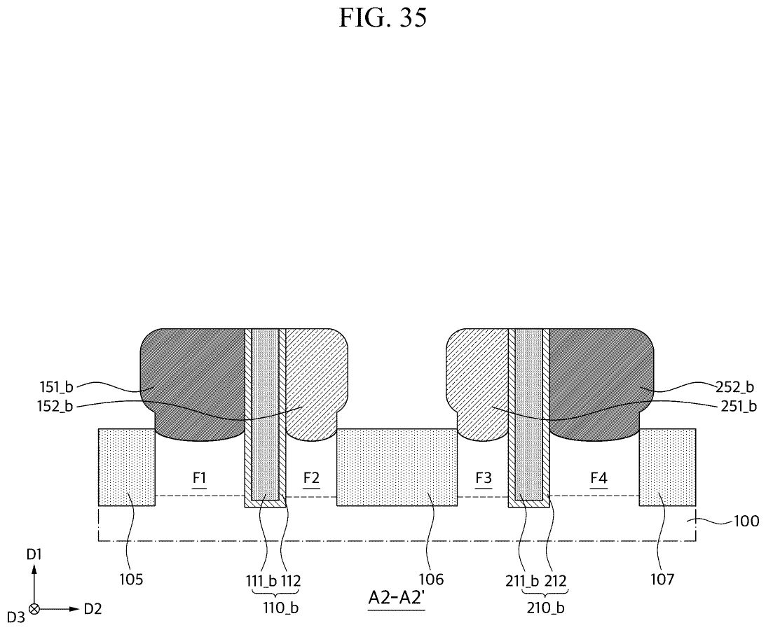

FIG. 31 to FIG. 35 are cross-sectional views illustrating a manufacturing method of the integrated circuit device 30 in the process sequence according to some example embodiments of the technical idea of the present disclosure. FIG. 31 to FIG. 33 are cross-sectional views illustrating cross-sectional structures according to the process sequence of a portion corresponding to the cross-section taken along line A1_b-A1_b′ of FIG. 9A. FIG. 34 and FIG. 35 are cross-sectional views illustrating cross-sectional structures according to the process sequence of a part corresponding to the cross-section taken along line A2_b-A2_b′ of FIG. 9B.

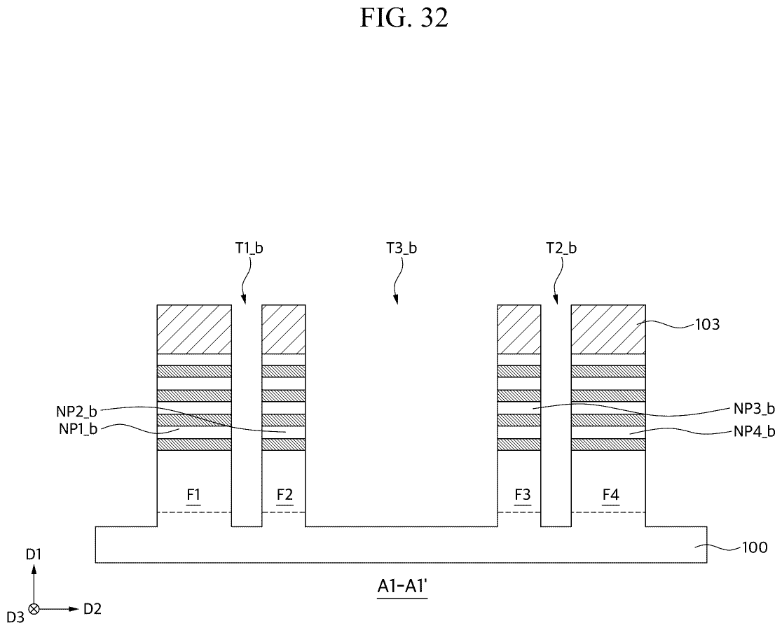

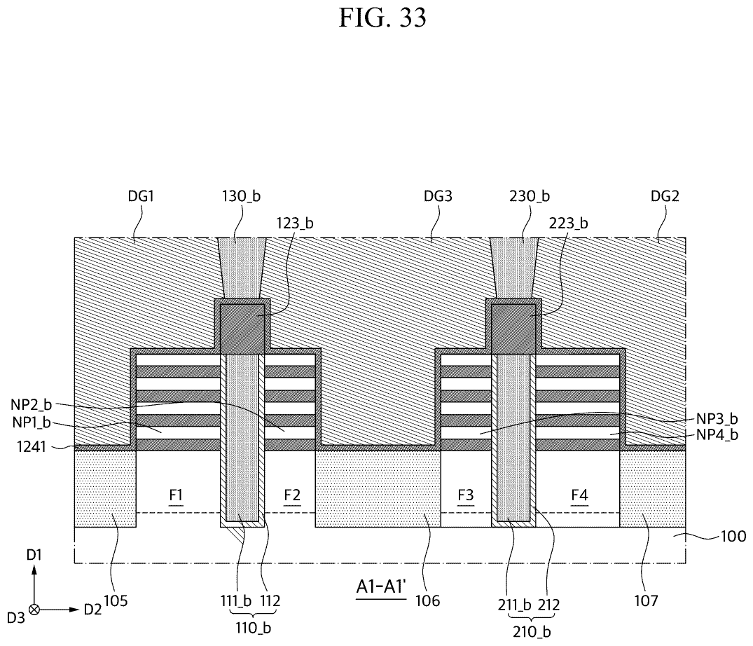

Specifically, FIG. 31 corresponds to FIG. 10A, FIG. 32 corresponds to FIG. 11, and FIG. 33 corresponds to FIG. 19A. Further, FIG. 34 corresponds to FIG. 20, and FIG. 35 corresponds to FIG. 21A. Below, described are the differences from the description of the manufacturing process of the integrated circuit device 10 with reference to FIG. 1 to FIG. 5.

Referring to FIG. 31, the capping layer 103S and a plurality of mask patterns MP_b may be formed on the stacked structure SS including the sacrificial film 101S and the semiconductor layer 102S alternately laminated on the substrate 100. Here, unlike the plurality of mask patterns MP illustrated in FIG. 10A, with regard to the plurality of mask patterns MP_b, the widths of the plurality of mask patterns MP_b spaced along the second direction D2 may be different from each other.

Referring to FIG. 32, the plurality of mask patterns MP_b may be used as an etching mask to etch a portion of the stacked structure SS and the substrate 100 to form a plurality of trenches (a first trench T1_b, a second trench T2_b, and a third trench T3_b). Here, like the plurality of trenches (the first trench T1, the second trench T2 and the third trench T3) illustrated in FIG. 11, the distance between the third trench T3_b and the first trench T1_b in the second direction D2 may be equal to the distance between the third trench T3_b and the second trench T2_b in the second direction D2. Further, unlike the first trench T1 and the second trench T2 illustrated in FIG. 11, the first trench T1_b and the second trench T2_b illustrated in FIG. 32 may have the same width in the second direction D2.

Referring to FIG. 33, in the plurality of trenches (the first trench T1_b, the second trench T2_b, and the third trench T3_b), formed may be field insulating films (the first field insulating film 105 to the third field insulating film 107) and the first insulating pillar 110_b and the second insulating pillar 210_b. The first insulating cap 123_b and the second insulating cap 223_b may be provided on the first insulating pillar 110_b and the second insulating pillar 210_b. After then, the upper insulating material 1241 may be deposited to cover side walls of the plurality of sacrificial films 101S and the plurality of nano patterns (the first nano pattern NP1_a to the fourth nano pattern NP4_a), and side walls of the first insulating cap 123_b and the second insulating cap 223_b. The upper insulating material 1241 may also cover the upper surfaces of the plurality of field insulating films (the first field insulating film 105 to the third field insulating film 107), the upper surfaces of the first insulating cap 123_b and the second insulating cap 223_b, and the upper surfaces of the uppermost nano-patterns (a first nano pattern NP1_b to a fourth nano pattern NP4_b). After depositing the upper insulating material 1241, a first upper insulting pillar 130_b overlapping the first insulating pillar 110_b and a second upper insulting pillar 230_b overlapping the second insulating pillar 210_b may be formed on the upper insulating material 1241.

According to some example embodiments, after forming the first upper insulting pillar 130_b and the second upper insulting pillar 230_b, the first dummy gate DG1 to the third dummy gate DG3 may be formed. However, depending on some example embodiments, after forming the first dummy gate DG1 to the third dummy gate DG3, the first upper insulting pillar 130_b and the second upper insulting pillar 230_b may also be formed.

According to some example embodiments, the first insulating pillar 110_b and the second insulating pillar 210_b may have the same width in the second direction D2.

According to some example embodiments, the width of the first nano pattern NP1_b in the second direction D2 and the width of the fourth nano pattern NP4_b in the second direction D2 may be the same, and the width of a second nano pattern NP2_b in the second direction D2 and the width of a third nano pattern NP3_b in the second direction D2 may be the same. Here, the width of the first nano pattern NP1_b may be greater than the width of the second nano pattern NP2_b.

According to some example embodiments, the first insulating pillar 110_b may be positioned offset from the center between the adjacent first field insulating film 105 and second field insulating film 106 in the second direction D2. Similarly, the second insulating pillar 210_b may also be positioned offset from the center between the adjacent second field insulating film 106 and third field insulating film 107 in the second direction D2.

Referring to FIG. 34, a portion of each of the plurality of nano patterns (the first nano pattern NP1_b to the fourth nano pattern NP4_b) (see FIG. 33), a portion of each of the plurality of insulating caps (the first insulating cap 123_b and the second insulating cap 223_b) (see FIG. 33), a portion of the plurality of sacrificial films 101S (see FIG. 33), and a portion of the upper insulating material 1241 (see FIG. 33) may be removed in the etching process.

According to some example embodiments, the portion of each of the plurality of nano patterns (the first nano pattern NP1_b to the fourth nano pattern NP4_b) (see FIG. 33), the portion of each of the plurality of insulating caps (the first insulating cap 123_b and the second insulating cap 223_b) (see FIG. 33), the portion of the plurality of sacrificial films 101S (see FIG. 33), and the portion of the upper insulating material 1241 (see FIG. 33), which are not covered by the mask are completely removed in the etching process. Further, in the etching process, a portion of the first active area F1 to the fourth active area F4 may be removed to form a first recess R1_b to a fourth recess R4_b. Any descriptions that overlap with those already described in detail with reference to FIG. 20 are omitted.

The first recess R1_b illustrated in FIG. 34 may have substantially the same width as the fourth recess R4_b in the second direction D2, and a second recess R2_b may have substantially the same width as a third recess R3_b in the second direction D2.

Referring to FIG. 35, the first source/drain area 151_b may be formed between a pair of nano sheets arranged along the third direction D3 on the first recess R1_b of the first active area F1. Further, the second source/drain area 152_b may be formed between a pair of nano sheets arranged along the third direction D3 on the second recess R2_b of the second active area F2. The third source/drain area 251_b may be formed between a pair of nano sheets arranged along the third direction D3 on the third recess R3_b of the third active area F3. The fourth source/drain area 252_b may be formed between a pair of nano sheets arranged along the third direction D3 on the fourth recess R4_b of the fourth active area F4.

According to some example embodiments, each of the first source/drain area 151_b to the fourth source/drain area 252_b may fill the corresponding recess among the first recess R1_b to the fourth recess R4_b. The first source/drain area 151_b illustrated in FIG. 35 may have substantially the same longest width in the second direction D2 as the fourth source/drain area 252_b, and the second source/drain area 152_b may have substantially the same longest width as the third source/drain area 251_b in the second direction D2. Further, the first source/drain area 151_b and the fourth source/drain area 252_b may be p-type source/drain areas with holes as carriers, and the second source/drain area 152_b and the third source/drain area 251_b may be n-type source/drain areas that have electrons as carriers.

The integrated circuit device according to some example embodiments of the present disclosure may provide a plurality of nano sheets that extend laterally from an insulating pillar interposed therebetween and are arranged parallel to each other in a direction intersecting the surface of a substrate. In this case, the width of the nano sheets interposed between a plurality of p-type source/drain regions and the width of the nano sheets interposed between a plurality of n-type source/drain regions may be different from each other.

The width of the PMOS nano sheets interposed between the plurality of p-type source/drain regions may be greater than the width of the NMOS nano sheets interposed between the plurality of n-type source/drain regions. Additionally, the width of the plurality of p-type source/drain regions may be greater than the width of the n-type source/drain regions. Simultaneously, the width of a first insulating pillar located between the plurality of p-type source/drain regions may be smaller than the width of a second insulating pillar located between the plurality of n-type source/drain regions.

In some example embodiments, since the width of the PMOS nano sheets serving as the channel of a PMOS transistor can be implemented to be greater than the width of the NMOS nano sheets serving as the channel of an NMOS transistor, more holes may be provided within the PMOS nano sheets, thereby improving the driving current of the PMOS transistor.

Furthermore, by providing the first insulating pillar with a reduced width, the degradation of stress applied to the plurality of p-type source/drain regions may be improved. Based on the aforementioned effects, an integrated circuit device with enhanced electrical reliability may be provided.

In the above, various example embodiments of the present disclosure are described in detail. However, it will be apparent to those with average knowledge in the technical field that scope of rights of this disclosure is not limited thereto, and various modifications and variations are possible without departing from the technical spirit of the present disclosure as set forth in the claims. Further, the above-described example embodiments may be implemented with some elements deleted, and each of the example embodiments may be implemented in combination with each other.

What is claimed is:

1. An integrated circuit device comprising:
a substrate;
a first insulating pillar extending in a first direction intersecting a surface of the substrate;
a first channel structure including a first sheet and a second sheet, the first sheet and the second sheet spaced apart in a second direction intersecting the first direction with the first insulating pillar interposed between the first sheet and the second sheet in the second direction;
a second insulating pillar spaced apart from the first insulating pillar in the second direction on the substrate; and
a second channel structure including a third sheet and a fourth sheet, the third sheet and the fourth sheet spaced apart in the second direction with the second insulating pillar interposed between the third sheet and the fourth sheet in the second direction, wherein
a sum of a width of the first channel structure and a width of the first insulating pillar in the second direction is equal to a sum of a width of the second channel structure and a width of the second insulating pillar in the second direction, and
the width of the first channel structure in the second direction is greater than the width of the second channel structure in the second direction.

2. The integrated circuit device of claim 1, further comprising:
a pair of first source/drain areas positioned at the first channel structure in a third direction intersecting the first direction and the second direction; and
a pair of second source/drain areas positioned at the second channel structure in the third direction,
wherein a longest width of the pair of first source/drain areas in the second direction is greater than a longest width of the pair of second source/drain areas in the second direction.

3. The integrated circuit device of claim 2, further comprising:
an upper insulating pillar on the first insulating pillar,
wherein the upper insulating pillar contacts a portion of the first insulating pillar between the pair of first conductive source/drain areas positioned at the first insulating pillar.

4. The integrated circuit device of claim 2, wherein the pair of first source/drain areas comprises a p-type impurity, and the pair of second source/drain areas comprises an n-type impurity.

5. The integrated circuit device of claim 1, further comprising:
a first insulating cap in contact with the first insulating pillar; and
a second insulating cap in contact with the second insulating pillar,
wherein a width of the second insulating cap in the second direction is greater than a width of the first insulating cap in the second direction.

6. The integrated circuit device of claim 1, further comprising:
a first gate line structure surrounding the first channel structure; and
a second gate line structure surrounding the second channel structure,
wherein a width of the first gate line structure in the second direction is greater than a width of the second gate line structure in the second direction.

7. The integrated circuit device of claim 1, further comprising:
a pair of gate cuts spaced apart in the second direction with the first insulating pillar interposed between the pair of gate cuts,
wherein the first insulating pillar is located at a center of the pair of gate cuts.

8. The integrated circuit device of claim 1, further comprising:
a first gate cut and a second gate cut spaced apart from each other in the second direction with the first insulating pillar interposed between the first gate cut and the second gate cut; and
a third gate cut spaced apart from the second gate cut in the second direction with the second insulating pillar interposed between the second gate cut and the third gate cut,
wherein a spacing distance between the first gate cut and the second gate cut is equal to a spacing distance between the second gate cut and the third gate cut.

9. An integrated circuit device comprising:
a substrate;
a first insulating pillar extending in a first direction intersecting a surface of the substrate;
a plurality of first nano sheets extending from the first insulating pillar in a second direction parallel to the surface of the substrate, the plurality of first nano sheets arranged in the first direction;
a plurality of second nano sheets extending toward the first insulating pillar in the second direction, the plurality of second nano sheets arranged in the first direction;
a second insulating pillar spaced apart from the first insulating pillar in the second direction on the substrate;
a plurality of third nano sheets extending from the second insulating pillar along the second direction, the plurality of third nano sheets arranged in the first direction; and
a plurality of fourth nano sheets extending from the second insulating pillar along the second direction, the plurality of fourth nano sheets arranged in the first direction,
wherein a width of the plurality of first nano sheets in the second direction is greater than a width of the plurality of second nano sheets in the second direction.

10. The integrated circuit device of claim 9, further comprising:
a first source/drain area positioned toward a third direction from the plurality of first nano sheets, the third direction intersecting with the first direction and the second direction, the first source/drain area including a p-type impurity; and
a second source/drain area positioned toward the third direction from the plurality of second nano sheets, the second source/drain area including an n-type impurity,
wherein a longest width of the first source/drain area in the second direction is greater than a longest width of the second source/drain area in the second direction.

11. The integrated circuit device of claim 9, wherein a width of the first insulating pillar in the second direction is equal to a width of the second insulating pillar in the second direction.

12. The integrated circuit device of claim 9, wherein
the first insulating pillar includes,
a first filling film extending in the first direction; and
a first insulating liner covering a portion of a side wall and a lower surface of the first filling film,
the second insulating pillar includes,
a second filling film extending in the first direction; and
a second insulating liner covering a portion of a side wall and a lower surface of the second filling film, and
a width of the second filling film in the second direction is equal to a width of the first filling film in the second direction.

13. The integrated circuit device of claim 12, further comprising:
a first insulating cap cover a portion of an upper surface of the first filling film; and
a second insulating cap cover a portion of an upper surface of the second filling film,
wherein a width of the second insulating cap in the second direction is equal to a width of the first insulating cap in the second direction.

14. The integrated circuit device of claim 13, further comprising:
an upper insulating pillar on the first insulating cap;
a first gate line surrounding the plurality of first nano sheets at first side of the upper insulating pillar along the second direction; and
a second gate line surrounding the plurality of second nano sheets at a second side of the upper insulating pillar along the second direction, the second side opposite the first side.

15. The integrated circuit device of claim 9, further comprising:
a p-type active area protruding from the substrate toward the plurality of first nano sheets; and
an n-type active area protruding from the substrate toward the plurality of second nano sheets,
wherein a width of the p-type active area in the second direction is greater than a width of the n-type active area in the second direction.

16. The integrated circuit device of claim 9, wherein
the plurality of third nano sheets are disposed between the plurality of second nano sheets and the plurality of fourth nano sheets,
the width of the plurality of first nano sheets in the second direction is equal to a width of the plurality of third nano sheets in the second direction, and
the width of the plurality of first nano sheets in the second direction is greater than a width of the plurality of fourth nano sheets in the second direction.

17. The integrated circuit device of claim 9, wherein
the plurality of third nano sheets are disposed between the plurality of second nano sheets and the plurality of fourth nano sheets,
the width of the plurality of first nano sheets in the second direction is greater than a width of the plurality of third nano sheets in the second direction, and
the width of the plurality of first nano sheets in the second direction is equal to a width of the plurality of fourth nano sheets in the second direction.

18. The integrated circuit device of claim 9, further comprising:
a pair of gate cuts spaced apart in the second direction with the first insulating pillar interposed between the pair of gate cuts,
wherein the first insulating pillar is offset from a center of a distance between the pair of gate cuts.

19. An integrated circuit device comprising:
a substrate having a plurality of active areas;
a plurality of field insulating films spaced apart from each other on the substrate in a first direction parallel to a surface of the substrate, the plurality of field insulating films defining the plurality of active areas;
a first insulating pillar extending in a second direction intersecting the first direction, the first insulating pillar between a pair of adjacent field insulating films among the plurality of field insulating films;
a second insulating pillar spaced apart from the first insulating pillar in the first direction on the substrate;
a plurality of first nano sheets extending from a first side wall of the first insulating pillar and arranged in parallel in a third direction intersecting the surface of the substrate;
a plurality of second nano sheets extending from a second side wall opposite to the first side wall of the first insulating pillar and arranged in parallel in the third direction;
a plurality of third nano sheets extending from a third side wall of the second insulating pillar and arranged in parallel in the third direction;
a plurality of fourth nano sheets extending from a fourth side wall opposite to the third side wall of the second insulating pillar and arranged in parallel in the third direction;
a plurality of p-type source/drain positioned in the second direction from the plurality of first nano sheets and the plurality of second nano sheets; and
a plurality of n-type source/drain areas positioned in the second direction from the plurality of third nano sheets and the plurality of fourth nano sheets, wherein
a sum of a width of the plurality of first nano sheets, a width of the plurality of second nano sheets and a width of the first insulating pillar in the first direction is equal to a sum of a width of the plurality of third nano sheets, a width of the plurality of fourth nano sheets and a width of the second insulating pillar in the first direction,
the width of the plurality of first nano sheets in the first direction is equal to the width of the plurality of second nano sheets in the first direction, and
the width of the plurality of first nano sheets is greater than the width of the plurality of third nano sheets in the first direction and the width of the plurality of fourth nano sheets in the first direction.

20. The integrated circuit device of claim 19, wherein the plurality of field insulating films comprises:
a first field insulating film spaced apart from the first side wall of the first insulating pillar;
a second field insulating film positioned between the first insulating pillar and the second insulating pillar; and
a third field insulating film spaced apart from the fourth side wall of the second insulating pillar,
wherein a difference between the width of the plurality of first nano sheets in the first direction and the width of the plurality of third nano sheets in the first direction ranges from 5% to 20% of a distance between a center of the first field insulating film and a center of the third field insulating film.
